(19) United States
(12) Patent Application Publication
(10) Pub. No.: US 2026/0190467 A1
(43) Pub. Date: Jul. 2, 2026

(54) MEMORIZED SOURCE-DRAIN STRAIN IN GATE-ALL-AROUND TRANSISTORS

(71) Applicant: Intel Corporation, Santa Clara, CA (US)

(72) Inventors: Stephen Cea, Hillsboro, OR (US); Michael L. Hattendorf, Portland, OR (US); Yuqian Gu, Hillsboro, OR (US); Rishabh Mehandru, Portland, OR (US)

(73) Assignee: Intel Corporation, Santa Clara, CA (US)

(21) Appl. No.: 19/002,304

(22) Filed: Dec. 26, 2024

(51) Int. Cl. H10D 84/85; H10D 84/01

(52) U.S. Cl. CPC H10D 84/851; H10D 84/017

(57) ABSTRACT

Integrated circuit (IC) devices having strained channels in gate-all-around transistors. An IC device may include first and second transistors with aligned first and second nanoribbon stacks having approximately equal lattice constants (differing substantially from a lattice constant of a substrate below the nanoribbon stacks) and a source-drain contact extending down at least partially between the nanoribbon stacks. Third and fourth nanoribbon stacks (aligned and parallel to the first and second nanoribbon stacks) may have approximately equal lattice constants, and the lattice constant of the substrate below the nanoribbon stacks may be between the lattice constant of the first and second nanoribbon stacks and the lattice constant of the third and fourth nanoribbon stacks. Sacrificial materials in source-drain trenches may generate the strain before removal and subsequent source-drain contact formation.

### BACKGROUND

In integrated circuit (IC) devices, transistor performance and reliability are often improved by straining channels, e.g., adding tensile or compressive stress along the direction of current flow for NMOS or PMOS (n-or p-type metal-oxide-semiconductor) devices, respectively. The strain is often produced by layout-or nest-dependent structures (such as isolation structures at standard-cell borders, from which channel strains diminish with distance from the strain-producing structure) or other inline structures (such as source-drain epi) whose strain production may interfere with optimizing other characteristics. For example, large source or drain semiconductor bodies may be needed to sufficiently strain attached transistor channels, but the required size of the source-drain bodies may increase resistances between source-drain contacts and the lowest nanoribbon channels in a stack. Further, strain generation by source- drain epi may be less effective in gate-all-around (GAA) transistors, as growing high quality (e.g., monocrystalline) epi in GAA structures is challenging, particularly for some conductivity types.

New techniques, structures, and materials are needed to improve GAA transistor performance and reliability.

### BRIEF DESCRIPTION OF THE DRAWINGS

The material described herein is illustrated by way of example and not by way of limitation in the accompanying figures. For simplicity and clarity of illustration, elements illustrated in the figures are not necessarily drawn to scale. For example, the dimensions of some elements may be exaggerated relative to other elements for clarity. Further, where considered appropriate, reference labels have been repeated among the figures to indicate corresponding or analogous elements, e.g., with the same or similar functionality. The disclosure will be described with additional specificity and detail through use of the accompanying drawings:

FIGS. 1A, 1B, and 1C illustrate cross-sectional plan and profile views of an integrated circuit (IC) device with transistor structures having strained channels in nanoribbons between trenches containing source and drain bodies and strain-generating dielectric materials, in accordance with some embodiments;

FIG. 2 is a flow chart of methods for straining transistor channels with sacrificial films, in accordance with some embodiments;

FIGS. 3A, 3B, 3C, 3D, 3E, and 3F illustrate cross-sectional plan and profile views of an IC device having strain-generating dielectric materials adjacent strained channels in nanoribbons in transistor structures, at various stages of manufacture, in accordance with some embodiments;

FIG. 4 illustrates a diagram of an example data server machine employing an IC device having transistor channels with strain produced by materials in source and drain trenches and retained by metal gate electrodes; and

FIG. 5 is a block diagram of an example computing device, in accordance with some embodiments.

### DETAILED DESCRIPTION

In the following detailed description, reference is made to the accompanying drawings that show, by way of illustration, specific embodiments in which the claimed subject matter may be practiced. These embodiments are described in sufficient detail to enable those skilled in the art to practice the subject matter. The various embodiments, although different, are not necessarily mutually exclusive. For example, a particular feature, structure, or characteristic described herein, in connection with one embodiment, may be implemented within other embodiments without departing from the spirit and scope of the claimed subject matter.

References within this specification to “one embodiment” or “an embodiment” mean that a particular feature, structure, or characteristic described in connection with the embodiment is included in at least one implementation encompassed within the present description. Therefore, the use of the phrase “one embodiment” or “in an embodiment” does not necessarily refer to the same embodiment. In addition, the location or arrangement of individual elements within each disclosed embodiment may be modified without departing from the spirit and scope of the claimed subject matter. The following detailed description is, therefore, not to be taken in a limiting sense, and the scope of the subject matter is defined only by the appended claims, appropriately interpreted, along with the full range of equivalents to which the appended claims are entitled.

The terms “over,” “to,” “between,” and “on” as used herein may refer to a relative position of one layer with respect to other layers. One layer “over” or “on” another layer or bonded “to” another layer may be directly in contact with the other layer or may have one or more intervening layers. One layer “between” layers may be directly in contact with the layers or may have one or more intervening layers.

The terms “coupled” and “connected,” along with their derivatives, may be used herein to describe structural relationships between components. These terms are not intended as synonyms for each other. Rather, in particular embodiments, “connected” may be used to indicate that two or more elements are in direct physical or electrical contact with each other. “Coupled” may be used to indicate that two or more elements are in either direct or indirect (with other intervening elements between them) physical or electrical contact with each other, and/or that the two or more elements co-operate or interact with each other (e.g., as in a cause-and-effect relationship, an electrical relationship, a functional relationship, etc.).

The term “circuit” or “module” may refer to one or more passive and/or active components that are arranged to cooperate with one another to provide a desired function. The term “signal” may refer to at least one current signal, voltage signal, magnetic signal, or data/clock signal. The meaning of “a,” “an,” and “the” include plural references. The meaning of “in” includes “in” and “on.”

The vertical orientation is in the z-direction and recitations of “top,” “bottom,” “above,” and “below” refer to relative positions in the z-dimension with the usual meaning. However, embodiments are not necessarily limited to the orientations or configurations illustrated in the figure.

The terms “substantially,” “close,” “approximately,” “near,” and “about,” generally refer to being within +/−10% of a target value (unless specifically specified). Unless otherwise specified in the specific context of use, the term “predominantly” means more than 50%, or more than half. For example, a composition that is predominantly a first constituent means more than half of the composition is the first constituent. The term “primarily” means the most, or greatest, part. For example, a composition that is primarily a first constituent means the composition has more of the first constituent than any other constituent. A composition that is primarily first and second constituents means the composition has more of the first and second constituents than any other constituent.

Unless otherwise specified the use of the ordinal adjectives “first,” “second,” and “third,” etc., to describe a common object, merely indicate that different instances of like objects to which are being referred and are not intended to imply that the objects so described must be in a given sequence, either temporally, spatially, in ranking or in any other manner.

For the purposes of the present disclosure, phrases “A and/or B” and “A or B” mean (A), (B), or (A and B). For the purposes of the present disclosure, the phrase “A, B, and/or C” means (A), (B), (C), (A and B), (A and C), (B and C), or (A, B and C).

Views labeled “cross-sectional,” “profile,” and “plan” correspond to orthogonal planes within a cartesian coordinate system. Thus, cross-sectional and profile views are taken in the x- z and y-z planes, and plan views are taken in the x-y plane. Typically, profile views in the x-z plane are cross-sectional views. Where appropriate, drawings are labeled with axes to indicate the orientation of the figure.

Structures, materials, and techniques are disclosed to improve transistor performance and reliability in integrated circuit (IC) devices having gate-all-around (GAA) transistors, for example, complementary devices improved by channel strain.

Sacrificial materials in source-drain trenches may be used to strain GAA transistor channels. After the channels are strained (whether tensioned or compressed), gate electrodes may be formed and retain the memorized strain before at least some of the strain-generating sacrificial materials are removed. The sacrificial material removal enables the formation in the trenches of source-drain bodies or contacts with optimized conductances, for example, metal contacts that closely approach the lowest nanoribbons channels instead of relatively large source-drain epi that produce strain, but at the cost of increased resistances (e.g., through the epi bodies and at contact interfaces).

Complementary sacrificial materials may be employed to uniformly deliver performance-improving strain to both n-and p-type channels, which may otherwise be troublesome (e.g., with source-drain epi in GAA transistors). For example, contractive dielectrics may tension n-type nanoribbon channels, and expansive oxides may compress p-type nanoribbon channels. Some or all of the strain-producing materials may be removed (e.g., in line with the channels), but some of the materials may be retained adjacent the source-drain epi and contacts.

Uniform strains in nanoribbon channels in aligned stacks (e.g., of a same conductivity type) may be evidenced by lattice constants substantially equal in the aligned nanoribbons, but different from a lattice constant in the substrate (e.g., below the nanoribbon stacks). Complementary strains (e.g., tensile and compressive) may be evidenced by substantially differing lattice constants in nanoribbon stacks of complementary conductivity types, for example, with a base or neutral lattice constant of the substrate between the strained, complementary lattice constants. The differing lattice constants in the complementary lines of transistors may be despite having split or etched-down source or drain bodies (e.g., incapable of delivering strain to channels) or similar metallization structures (e.g., incapable of delivering differential strain to channels in complementary transistors).

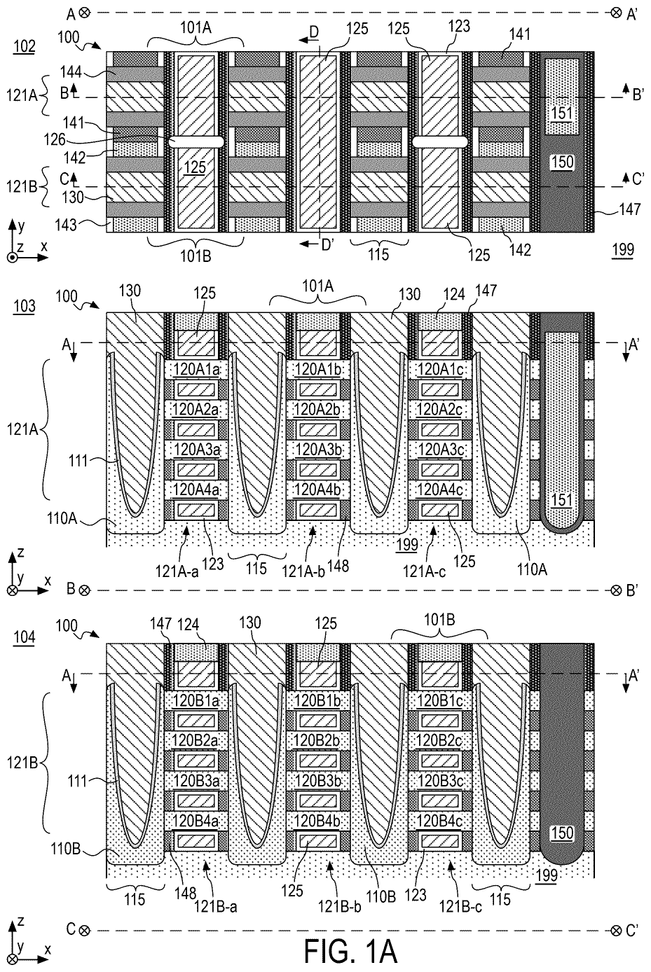

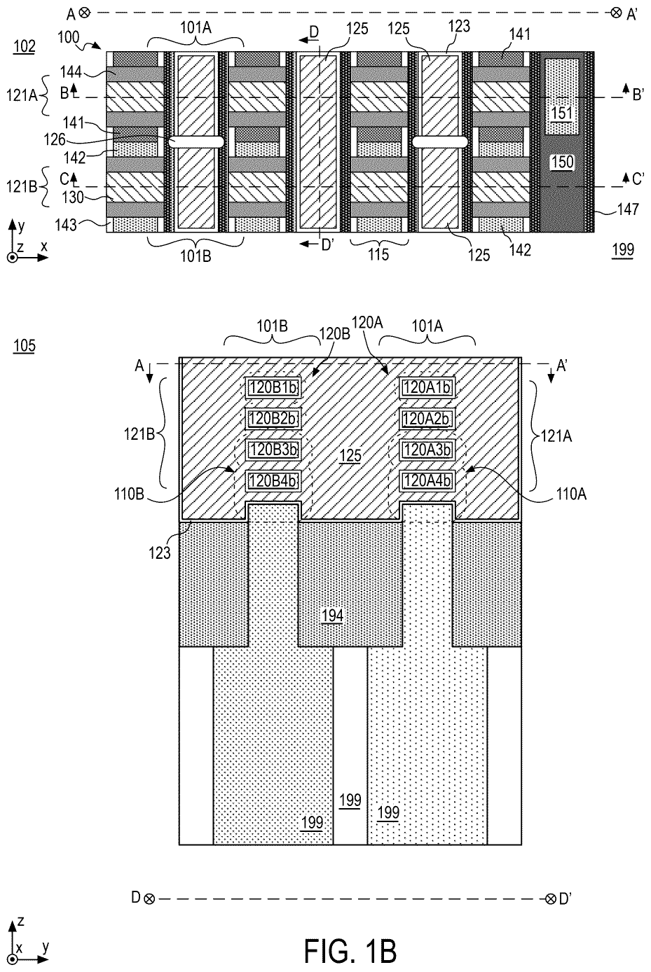

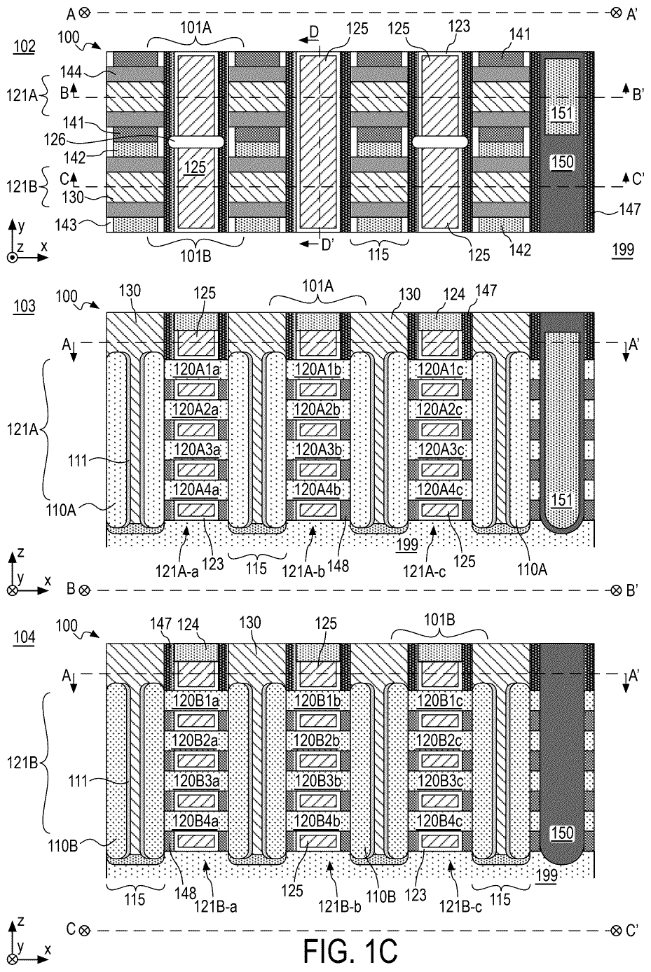

FIGS. 1A, 1B, and 1C illustrate cross-sectional plan and profile views of an IC device 100 with transistor structures 101A, 101B having strained channels in nanoribbons 120A, 120B between trenches 115 containing source and drain bodies 110A, 110B and strain-generating dielectric materials 141, 142, in accordance with some embodiments. FIGS. 1A and 1C include plan view 102 and profile views 103, 104. FIG. 1B includes plan view 102 and profile view 105. The x-y viewing plane A-A′ of plan view 102 shows the orientation of x-z viewing planes B-B′ and C-C′ of profile views 103, 104, respectively, and of y-z viewing plane D-D′ of profile view 105. FIG. 1C shows a device 100 similar to that described at FIG. 1A, but with different source and drain bodies 110A, 110B, for example.

FIG. 1A illustrates stacks 121A, 121B of strained-channel nanoribbons 120A, 120B in transistor structures 101A, 101B, respectively. In exemplary embodiments of FIGS. 1A-1C, transistor structures 101A are n-type structures 101A, and transistor structures 101B are p-type structures 101B. Transistor structures 101A, 101B and stacks 121A, 121B of a given conductivity type are lined up along a shared axis (e.g., centerplane) extending in the x-direction.

Dielectric materials 141, 142 may generate complementary strains that improve performance of complementary transistor structures 101A, 101B. For example, material 141 may generate tensile strain to improve the performance and reliability of nanoribbons 120A in n-type transistor structures 101A, and material 142 may generate compressive strain to improve the performance and reliability of nanoribbons 120B in p-type transistor structures 101B. In many embodiments, one or both of materials 141, 142 are at least somewhat sacrificial materials 141, 142, e.g., with some or all of materials 141, 142 removed adjacent one or both axes of transistor structures 101A, 101B and stacks 121A, 121B. Strain delivered to channels in nanoribbons 120A, 120B (e.g., by materials 141, 142 during processing) may be retained (e.g., “memorized”) by metal gate electrodes 125, even if sacrificial materials 141, 142 are removed. In exemplary embodiments of FIGS. 1A and 1B, materials 141, 142 are dielectric materials 141, 142, but other materials 141, 142 may be used. For example, fully sacrificial materials 141, 142 (or retained materials 141, 142 electrically isolated by dielectric structures 144 and spacer 147) need not be dielectric materials 141, 142.

In FIG. 1A, view 102 shows groups of transistor structures 101A, 101B aligned on separate centerplanes B-B′ and C-C′, respectively, which are viewing planes B-B′ and C-C′ of views 103, 104. Source and drain contact structures 130 of structures 101A, 101B are also aligned on respective centerplanes B-B′ and C-C′. Contact structures 130 are between corresponding stacks 121A, 121B (as shown at views 103, 104) and over (and extending into) corresponding source and drain bodies 110A, 110B. Gate electrodes 125 are over (and between) corresponding nanoribbons 120A, 120B in stacks 121A, 121B, between source and drain contact structures 130 (as shown at views 103, 104). Nanoribbons 120A, 120B and stacks 121A, 121B extend in the x-directions through electrodes 125, as shown at views 103, 104. Spacers 147 are between electrodes 125 and contact structures 130, e.g., providing electrical isolation.

Contact structures 130 are metallization structures 130 in transistor structures 101A, 101B that contact semiconductor source and drain bodies 110A, 110B in structures 101A, 101B (as shown in views 103, 104). Contact structures 130 in adjacent, complementary transistor structures 101A, 101B are in a same trench 115 between gate electrodes 125 (and between spacers 147 on electrodes 125). Trenches 115 are not (e.g., are no longer) cavities or voids between adjacent groups of gate electrodes 125 and sidewall spacers 147 (e.g., in a given transistor structure 101A or 101B), but are filled with dielectrics (e.g., materials 141, 142; layers 143; and structures 144) adjacent metallization structures 130.

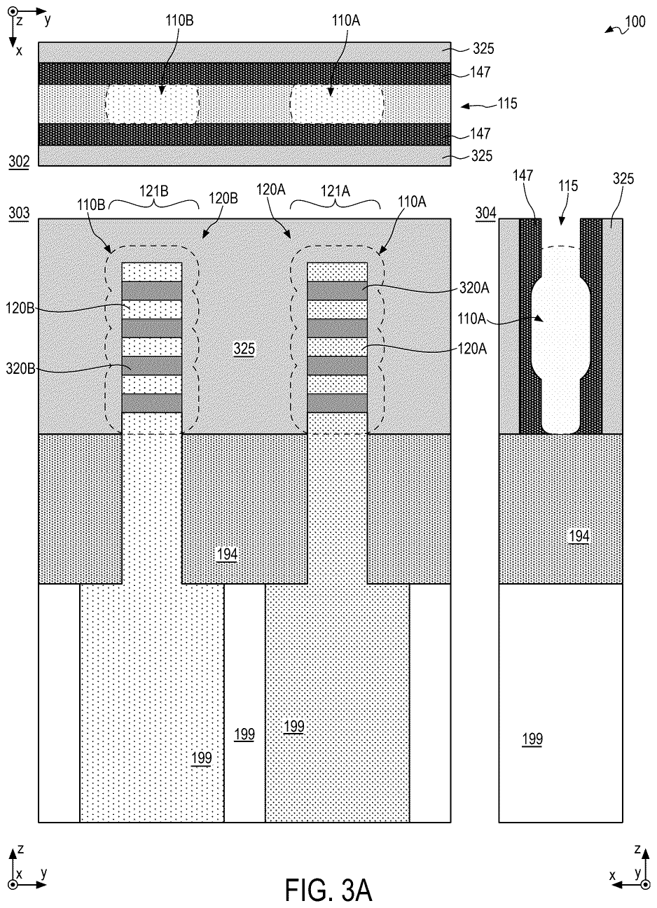

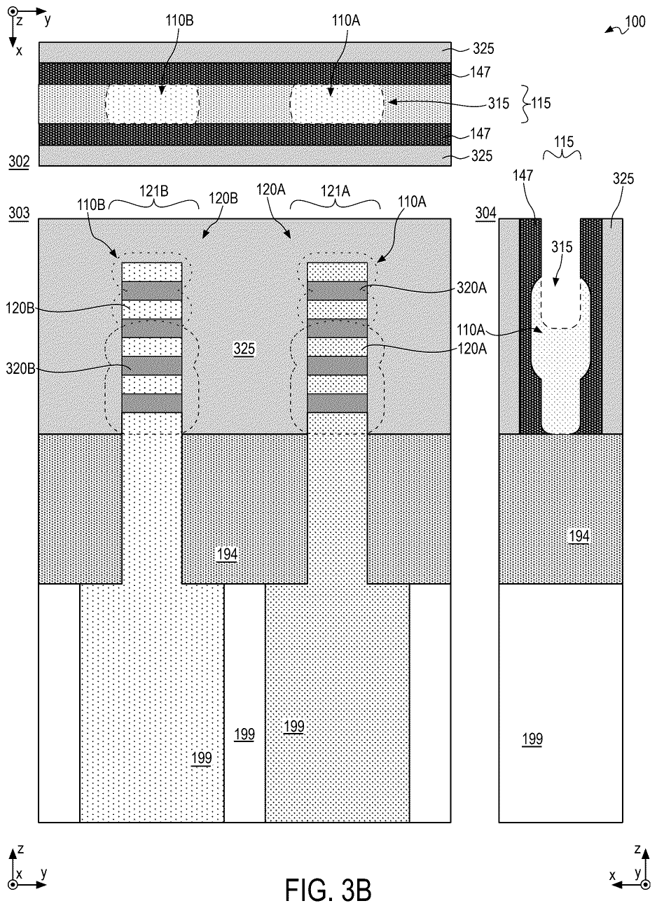

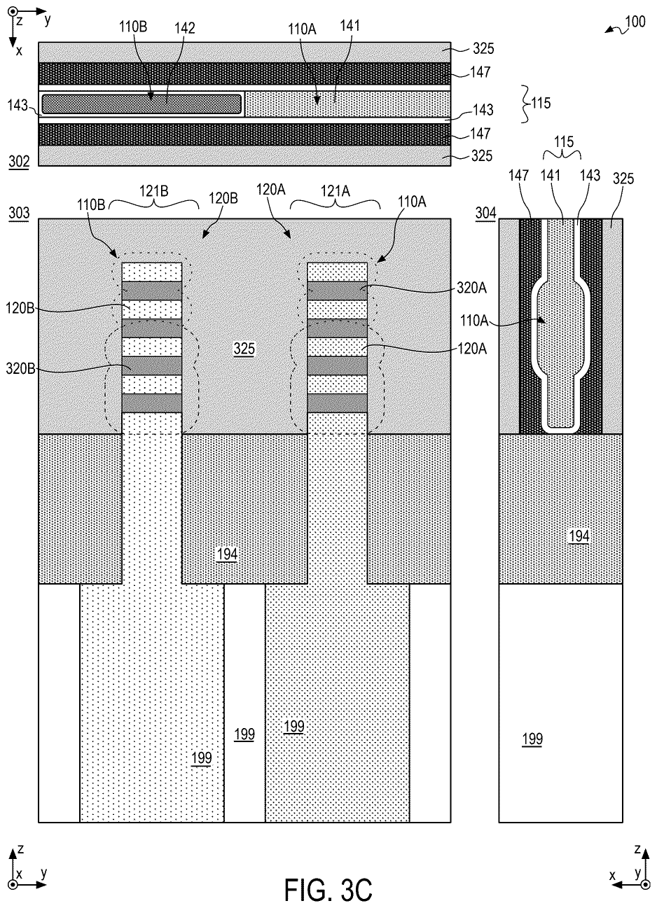

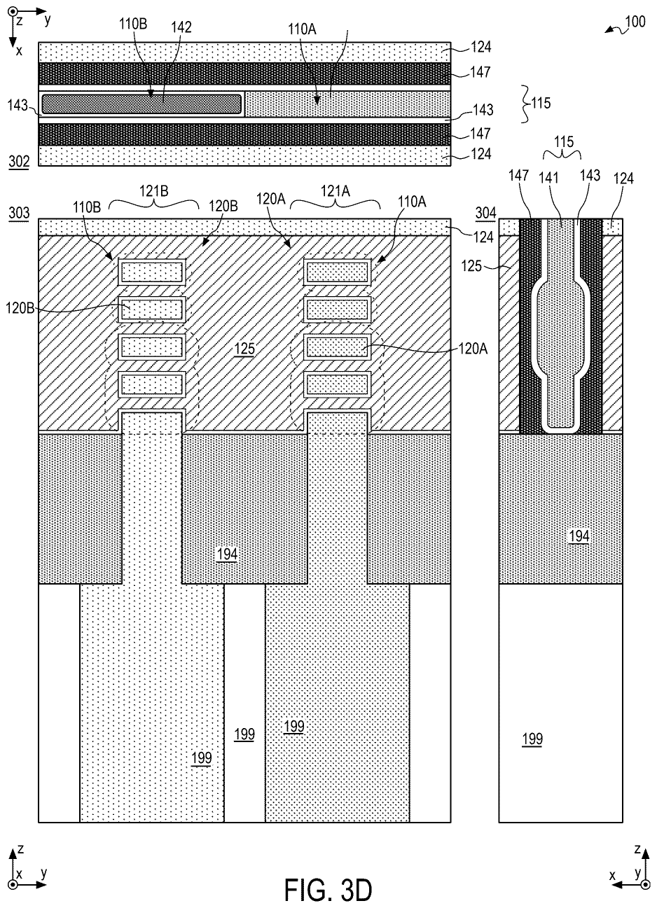

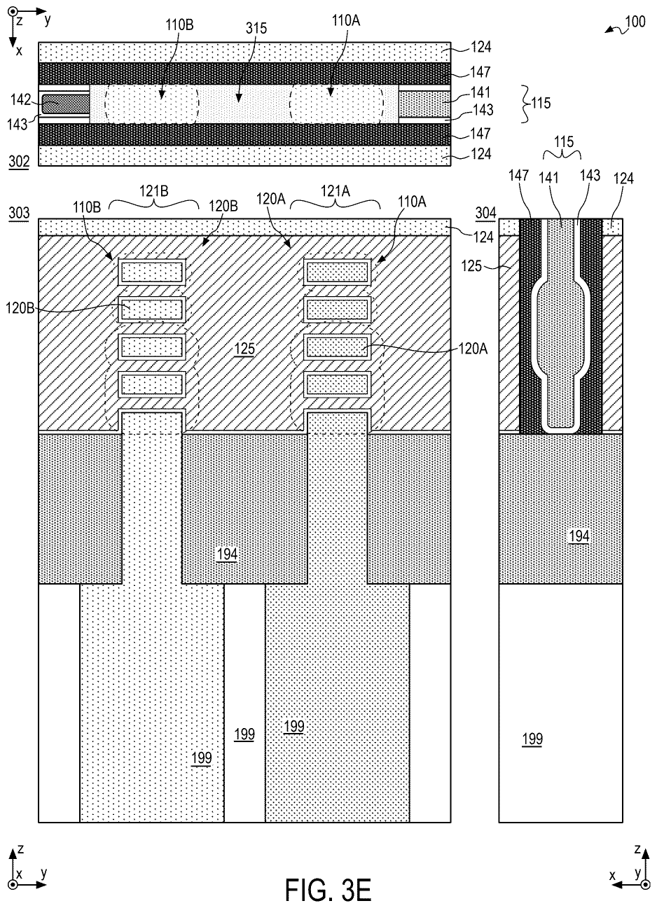

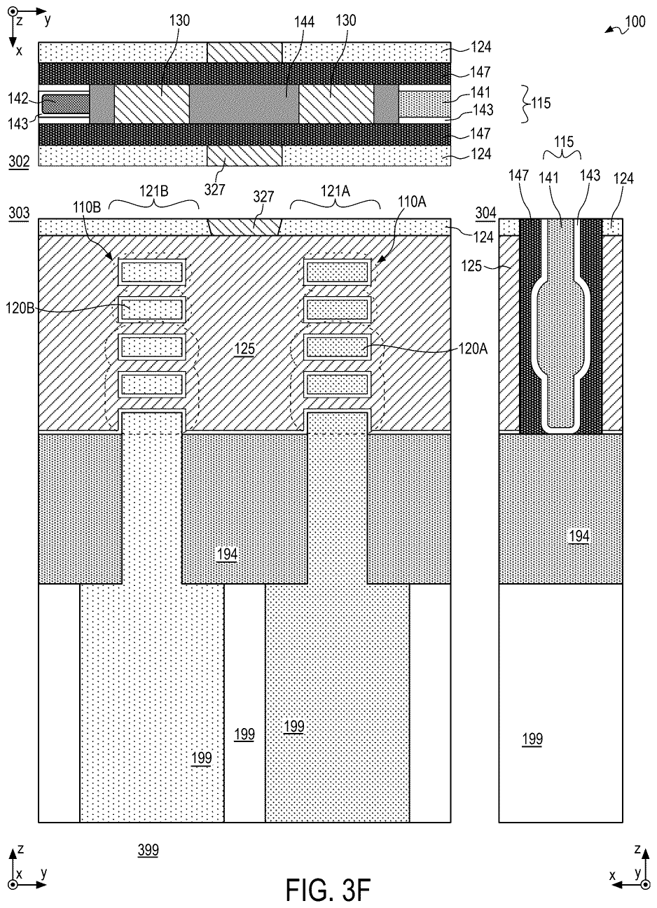

Contact structures 130 are each in (e.g., through) a dielectric structure 144, which is in (e.g., through) dielectric layer 143 and either dielectric material 141 or 142. Dielectric layer 143 is on (e.g., conformally on) spacers 147. Dielectric materials 141, 142 are on (e.g., contained by or within) layer 143, in trenches 115 between gate electrodes 125 (and between spacers 147 on electrodes 125). In some embodiments, multiple layers 143 are in a same trench 115, for example, both around and between materials 141, 142 (e.g., as described at FIG. 3C, etc.). Dielectric structure 144 is advantageously of a low-k (low-permittivity) dielectric material, e.g., to provide electrical isolation and minimize parasitic capacitances between adjacent structures. In some embodiments, dielectric structure 144 includes oxygen, e.g., in an oxide (such as an oxide of silicon). Dielectric structure 144 advantageously provides protection (e.g., chemical protection) to metallization structures 130. In some embodiments, dielectric structure 144 includes nitrogen, e.g., in a nitride (such as a nitride of silicon). In some embodiments, both of a pair of contact structures 130 in a given trench 115 are in and through a same, single structure 144, e.g., without any of dielectric materials 141, 142 or layers 143 between the contact structures 130.

Dielectric materials 141, 142 may produce strain in adjacent stacks 121A, 121B and structures 101A, 101B, respectively. Dielectric material 141 may be a contractive material (e.g., whose volume reduced after deposition) that generates tensile stresses (e.g., along centerplane B-B′) and causes tensile strain in nanoribbons 120A in stacks 121A. For example, in some embodiments, material 141 is a cured oxide of silicon that was deposited uncured and was then cured and shrunk (e.g., decreased in volume) following deposition. Dielectric material 142 may be an expansive material (e.g., whose volume increased after deposition) that generates compressive stresses (e.g., along centerplane C-C′) and causes compressive strain in nanoribbons 120B in stacks 121B. For example, in some embodiments, material 142 includes oxidized silicon (such as amorphous silicon) that was expanded (e.g., increased in volume) by oxidization after deposition. One or both of materials 141, 142 may be absent from device 100, e.g., fully sacrificial materials 141 and 142.

Contact structures 130 in transistor structures 101A are in trenches 115 between stacks 121A of nanoribbons 120A, and dielectric material 141 is adjacent contact structures 130 in trench 115 between stacks 121A of nanoribbons 120A. Contact structures 130 in transistor structures 101B are in trench 115 between stacks 121B of nanoribbons 120B, and dielectric material 142 is adjacent contact structures 130 in trench 115 between stacks 121B of nanoribbons 120B.

In some embodiments, device 100 includes dielectric layers 143 (e.g., to provide etch selectivities or to protect adjacent structures (e.g., nanoribbons 120) from materials 141, 142 during processing. For example, without the protection of layers 143, materials 141, 142 may cause undesired oxidation of contacted structures. In many embodiments, liner layer 143 includes nitrogen. In some embodiments, liner layer 143 includes silicon (e.g., in a nitride of silicon).

In FIG. 1A, views 103, 104 illustrate complementary transistor structures 101A, 101B with complementarily strained nanoribbons 120A, 120B. View 103 shows device 100 having a group of transistor structures 101A aligned (e.g., centered; symmetric about) on viewing plane B-B′, which extends in the x-directions. Multiple stacks 121A of nanoribbons 120A (e.g., nanoribbons 120A1a-120A4a, 120A1b-120A4b, 120A1c-120A4c) are over substrate 199. Nanoribbons 120A in each stack 121A are extending in the x-directions and aligned with nanoribbons 120A in other stacks 121A. Each stack 121A is in a distinct transistor structure 101A.

In exemplary embodiments of FIG. 1A, transistor structures 101A are n-type structures 101A, and source and drain semiconductor bodies 110A include an n-type dopant. Each body 110A is between and coupled with stacks 121A of nanoribbons 120A. Each body 110A is in contact with a contact structure 130.

Nanoribbons 120A (e.g., nanoribbons 120A1a-120A4a, 120A1b-120A4b,120A1c-120A4c) have substantially equal lattice constant(s) in each stack 121A (e.g., stacks 121A-a, 121A-b, 121A-c), which are substantially different than a lattice constant of substrate 199, e.g., under or below stacks 121A. For example, nanoribbons 120A at a same level (e.g., nanoribbons 120A1a, 120A1b, 120A1c) in each stack 121A may have substantially equal lattice constants (e.g., within 0.2%). Although the strain within a stack 121A may increase up the stack 121A (e.g., with nanoribbon 120A1a (or 120A1b or 120A1c) having a lattice constant larger than nanoribbon 120A2a (or 120A2b or 120A2c), which has a lattice constant larger than nanoribbon 120A3a (or 120A3b or 120A3c), which has a lattice constant larger than nanoribbon 120A4a (or 120A4b or 120A4c)), each nanoribbon 120A may have a lattice constant closer to a nearest nanoribbon 120A (e.g., within 0.2%) than to the lattice constant of substrate 199 (e.g., which may be 0.3% less than the lowest nanoribbon 120A4a (or 120A4b or 120A4c)). The matched lattice constants of nanoribbons 120A in different, aligned stacks 121A are enabled by strain memorized and provided by gate electrodes 125.

In exemplary embodiments of FIG. 1A, n-type structures 101A are subject to tensile stress, and semiconductor nanoribbons 120A in stacks 121A have a crystalline lattice with a larger lattice constant than a crystalline lattice of substrate 199 under or below stacks 121A. In many embodiments, nanoribbons 120A in each stack 121A have lattice constants between 0.3% and 1.5% greater than the unstrained lattice constant of substrate 199. In many embodiments, substrate 199 has an unstrained lattice constant, and nanoribbons 120A in each stack 121A have lattice constants varying by less than 0.5% (e.g., of the unstrained lattice constant of substrate 199). For example, nanoribbons 120A in each stack 121A have lattice constants varying between 0.3% and 0.8% greater than the unstrained lattice constant of substrate 199. In other embodiments, nanoribbons 120A in each stack 121A have lattice constants varying between 1.0% and 1.5% greater than the unstrained lattice constant of substrate 199. The larger lattice constants of nanoribbons 120A in different, aligned stacks 121A are enabled by tensile strain memorized and provided by gate electrodes 125.

View 104 shows device 100 having a group of transistor structures 101B aligned (e.g., centered) on viewing plane C-C′, which extends in the x-directions. Multiple stacks 121B of nanoribbons 120B (e.g., nanoribbons 120B1a-120B4a, 120B1b-120B4b, 120B1c-120B4c) are over substrate 199. Nanoribbons 120B in each stack 121B are extending in the x-directions and aligned with nanoribbons 120B in other stacks 121B. Each stack 121B is in a distinct transistor structure 101B.

In exemplary embodiments of FIG. 1A, transistor structures 101B are p-type structures 101B, and source and drain semiconductor bodies 110B include a p-type dopant. Each body 110B is between and coupled with stacks 121B of nanoribbons 120B. Each body 110B is in contact with a contact structure 130.

Nanoribbons 120B (e.g., nanoribbons 120B1a-120B4a, 120B1b-120B4b,120B1c-120B4c) have substantially equal lattice constant(s) in each stack 121B (e.g., stacks 121B-a, 121B-b, 121B-c), which are substantially different than a lattice constant of substrate 199, e.g., under or below stacks 121B. For example, nanoribbons 120B at a same level (e.g., nanoribbons 120B1a, 120B1b, 120B1c) in each stack 121B may have substantially equal lattice constants (e.g., within 0.2%). Although the strain within a stack 121B may increase up the stack 121B (e.g., with nanoribbon 120B1a (or 120B1b or 120B1c) having a lattice constant shorter than nanoribbon 120B2a (or 120B2b or 120B2c), which has a lattice constant shorter than nanoribbon 120B3a (or 120B3b or 120B3c), which has a lattice constant shorter than nanoribbon 120B4a (or 120B4b or 120B4c)), each nanoribbon 120B may have a lattice constant closer to a nearest nanoribbon 120B (e.g., within 0.2%) than to the lattice constant of substrate 199 (e.g., which may be 0.3% greater than the lowest nanoribbon 120B4a (or 120B4b or 120B4c)). The matched lattice constants of nanoribbons 120B in different, aligned stacks 121B are enabled by strain memorized and provided by gate electrodes 125.

In exemplary embodiments of FIG. 1A, p-type structures 101B are subject to compressive stress, and semiconductor nanoribbons 120B in stacks 121B have a crystalline lattice with a smaller lattice constant than a crystalline lattice of substrate 199 under or below stacks 121B. In many embodiments, nanoribbons 120B in each stack 121B have lattice constants between 0.3% and 1.5% less than the unstrained lattice constant of substrate 199. In many embodiments, substrate 199 has an unstrained lattice constant, and nanoribbons 120B in each stack 121B have lattice constants varying by less than 0.5% (e.g., of the unstrained lattice constant of substrate 199). For example, nanoribbons 120B in each stack 121B have lattice constants varying between 0.3% and 0.8% shorter than the unstrained lattice constant of substrate 199. In other embodiments, nanoribbons 120B in each stack 121B have lattice constants varying between 1.0% and 1.5% less than the unstrained lattice constant of substrate 199. The smaller lattice constants of nanoribbons 120B in different, aligned stacks 121B are enabled by compressive strain memorized and provided by gate electrodes 125.

Nanoribbons 120 provide channel regions for transistor structures 101 and may be of any (e.g., semiconducting) material(s) suitable for use as channel regions. Nanoribbons 120A in stack 121A may be the same as or different than nanoribbons 120B in stack 121B. Transistor structures 101A, 101B may have nanoribbons 120A, 120B of different compositions, etc. Deploying nanoribbons 120A, 120B of different material compositions may improve performance by allowing the employment of optimal materials for different transistor structures 101. In many embodiments, transistor structures 101A, 101B are of complementary conductivity types (e.g., n-and p-types). In many embodiments, structure 101A is an n-type transistor structure 101A, and first nanoribbons 120A are predominantly silicon (e.g., coupled with predominantly silicon source or drain bodies 110A). In many embodiments, structure 101B is a p-type transistor structure 101B, and second nanoribbons 120B include silicon and/or germanium (e.g., coupled with source or drain bodies 110B of silicon and germanium). Nanoribbons 120 may have any suitable width (e.g., in the y-dimension), for example, being nanowire nanoribbons 120 (with smaller widths) or nanosheet nanoribbons 120 (with larger widths).

Isolation 150 (which may include dielectric material 151) may be at the edges of a standard cell. In some conventional IC devices, an isolation structure might be used to strain transistor channels within a standard cell, but such strain is typically layout-or nest-dependent, e.g., diminishing with the distance from the isolation. In the novel device 100 described, strain in transistor structures 101A, 101B is independent of isolation 150 (and position relative to isolation 150), e.g., delivered by dielectric materials 141, 142 (and/or retained or memorized by electrodes 125) and distributed uniformly through each of transistor structures 101A or 101B. For example, nanoribbons 120A (e.g., nanoribbons 120A1a-120A4a, 120A1b-120A4b,120A1c-120A4c) in each stack 121A (e.g., stacks 121A-a, 121A-b, 121A-c) have substantially equal lattice constants despite the different relative distances to isolation 150. Nanoribbons 120B (e.g., nanoribbons 120B1a-120B4a, 120B1b-120B4b, 120B1c-120B4c) in each stack 121B (e.g., stacks 121B-a, 121B-b, 121B-c) have substantially equal lattice constants despite the different relative distances to isolation 150.

Contact structures 130 are each coupled with the pairs of stacks 121 of nanoribbons 120 that structures 130 are between. Advantageously, structures 130 extend down to between one or more pairs of adjacent and aligned nanoribbons 120, which may improve conductance from lower nanoribbons 120 up to upper surfaces of contact structures 130. In many conventional IC devices with strained transistor channels, transistors depend on strain generation by source and drain bodies, which may require large source and drain semiconductor bodies (e.g., epitaxial bodies, from below a lowest nanoribbon to above a highest nanoribbons). Such semiconductor bodies may limit conductances from lower nanoribbons to contacts over the semiconductor bodies.

Dielectric materials 141, 142 (by generating strain independent of epitaxial bodies) may enable highly conductive metallization structures 130 penetrating down towards, and even below, lower nanoribbons 120 in stacks 121. In exemplary embodiments of view 103, contact structures 130 are between a lowermost nanoribbon 120A1 (e.g., nanoribbon 120A4a or 120A4b) of a first stack 121A (e.g., stack 121A-a or stack 121A-b) of nanoribbons 120A and a lowermost nanoribbon 120A1 (e.g., nanoribbon 120A4b or 120A4c) of a second stack 121A (e.g., stack 121A-b or stack 121A-c) of nanoribbons 120A. A shared axis of lowermost nanoribbons 120A4a, 120A4b, 120A4c of stacks 121A intersects contact structures 130 between stacks 121A. In exemplary embodiments of view 104, contact structures 130 are between a lowermost nanoribbon 120B1 (e.g., nanoribbon 120B4a or 120B4b) of a first stack 121B (e.g., stack 121B-a or stack 121B-b) of nanoribbons 120B and a lowermost nanoribbon 120B1 (e.g., nanoribbon 120B4b or 120B4c) of a second stack 121B (e.g., stack 121B-b or stack 121B-c) of nanoribbons 120B. A shared axis of lowermost nanoribbons 120B4a, 120B4b, 120B4c of stacks 121B intersects contact structures 130 between stacks 121B.

Metallization structures 130 may penetrate downward and below some, but not all, nanoribbons 120 in stacks 121. In some embodiments, contact structures 130 are only down to between an uppermost nanoribbon 120A1 (e.g., nanoribbon 120A1a or 120A1b) of a first stack 121A (e.g., stack 121A-a or stack 121A-b) of nanoribbons 120A and an uppermost nanoribbon 120A1 (e.g., nanoribbon 120A1b or 120A1c) of a second stack 121A (e.g., stack 121A-b or stack 121A-c) of nanoribbons 120A. A shared axis of uppermost nanoribbons 120A1a, 120A1b, 120A1c of stacks 121A intersects contact structures 130 between stacks 121A. In some embodiments, contact structures 130 are only down to between an uppermost nanoribbon 120B1 (e.g., nanoribbon 120B1a or 120B1b) of a first stack 121B (e.g., stack 121B-a or stack 121B-b) of nanoribbons 120B and an uppermost nanoribbon 120B1 (e.g., nanoribbon 120B1b or 120B1c) of a second stack 121B (e.g., stack 121B-b or stack 121B-c) of nanoribbons 120B. A shared axis of uppermost most nanoribbons 120B1a, 120B1b, 120B1c of stacks 121B intersects contact structures 130 between stacks 121B.

Contact structures 130 need not be of complementary materials that generate complementary strains in the complementary lines of transistor structures 101A, 101B (e.g., due to the use of dielectric materials 141, 142 to generate complementary strains). In many embodiments, the first metallization structures 130 in and between transistor structures 101A include a same composition as the second metallization structures 130 in and between the transistor structures 101B. Contact structures 130 may be of any suitable material(s), e.g., conductive materials (such as metals) with low contact resistances with semiconductor materials of bodies 110. Structures 130 may couple bodies 110 (and transistor structures 101) to interconnect layers and networks (not shown), e.g., over transistor structures 101. In many embodiments, contact structures 130 include one or more of copper, gold, tantalum, cobalt, tungsten, ruthenium, molybdenum, titanium, aluminum, and nickel, including in alloys. In some embodiments, structures 130 include nitrides of metals, e.g., tantalum and titanium. Structures 130 may include other electrically conductive materials, including non-metals. In some embodiments, structures 130 include one or more metal layers deposited on semiconductor bodies 110. Structures 130 (and/or bodies 110) may include an interface layer 111 having metal alloyed or otherwise bonded or interfaced with a surface of semiconductor body 110, for example, a highly conductive contact or interface layer on crystalline semiconductor.

As shown in views 103, 104, source or drain bodies 110 are electrically and physically coupled to opposite ends of channel-region nanoribbons 120. In many embodiments, transistor structures 101 are each physically symmetrical about nanoribbons 120 (e.g., channel regions) and gate electrodes 125, and identifiers “drain” and “source” for bodies 110 may be reversed interchangeably in many contexts. However, the classification of source or drain bodies 110 may be by the electrical relationships of transistor structures 101 and bodies 110 to other components in a given circuit (e.g., and the consequent direction of current flow through structures 101 and bodies 110). Some source or drain bodies 110 may simultaneously be a source body 110 in one transistor structure 101 and a drain body 110 in another transistor structure 101.

Source or drain bodies 110 may be impurity doped regions, e.g., regions of semiconductor material doped with one or more electrically active impurities and having increased charge-carrier availabilities and associated conductivities. Bodies 110 in different transistor structures 101 may be doped with an opposite type (e.g., n-or p-type) or of similar type. Source or drain bodies 110 may include a predominant semiconductor material, and one or more n-dopants (such as phosphorus, arsenic, or antimony) or p-type impurities (such as boron or aluminum). Other dopant materials may be used. Bodies 110 may be substantially crystalline. Source or drain bodies 110 may be polycrystalline or substantially monocrystalline, e.g., having long-range order at least adjacent ends of nanoribbons 120 and merging or joining into a unitary body with few grain boundaries. Source or drain bodies 110 may include multiple portions, for example, portions grown separately, including at earlier and later operations of a manufacturing process. For example, in some embodiments, interface layers 111 of bodies 110 are grown after the bulk of bodies 110 are grown, e.g., just before contacts 130 are formed on bodies 110. Layers 111 may include more dopant(s) or a different dopant than in the bulk of bodies 110, e.g., for a reduced contact resistance between bodies 110 and contacts 130. Layers 111 may include a metal-semiconductor compound (such as a silicide, etc.) at an interface of bodies 110 and contacts 130.

Any suitable means of formation may be used. Bodies 110 may be epitaxially grown semiconductor regions, for example, of a Group IV semiconductor material (e.g., Si, Ge, SiGe, GeSn alloy). Other semiconductor materials may be employed. Bodies 110 may be unitary bodies 110 and continuous between adjacent and aligned nanoribbons 120 (e.g., nanoribbons 120 in adjacent stacks 121 and aligned on a shared axis or centerline). In many embodiments, bodies 110 are on adjacent and aligned nanoribbons 120 (e.g., on both sides of a trench 115 between stacks 121 of nanoribbons 120), but with a contact structure 130 between one or more pairs of adjacent and aligned nanoribbons 120. In some such embodiments, as in views 103 and 104, bodies 110 with a contact structure 130 between one or more pairs of adjacent and aligned nanoribbons 120 are continuous below the structure 130 (e.g., below one or more of the pairs—for example, all of the pairs—of adjacent and aligned nanoribbons 120 in the stacks 121).

Bodies 110 need not span trenches 115 (e.g., as described further at FIG. 1C). In some embodiments, a pair of bodies 110 bookend each contact structure 130, with a body 110 on each side of each contact structure 130, e.g., merged on the nanoribbons 120 of same stacks 121, but not merged or continuous between different stacks 121. In some embodiments, contact structure 130 is in contact with a pair of first and second bodies 110 between stacks 121 of nanoribbons 120, in trench 115, a first of the semiconductor bodies 110 is coupled with the first stack 121 of nanoribbons 120, and a second of the semiconductor bodies 110 is coupled with the second stack 121 of nanoribbons 120. In such embodiments, structure 130 is coupled with each stack 121 of nanoribbons 120 by the respective first or second body 110. Semiconductor bodies 110 not merged or continuous between different stacks 121 may be formed by any suitable means, e.g., split by an etch through a previously unitary body 110, grown and merged only with nanoribbons 120 of same stacks 121 and not across trench 115, etc. In some conventional devices, epi bodies (e.g., large semiconductor bodies spanning a trench between nanoribbon stacks) are needed to provide channel strain, but materials 141, 142 in IC device 100 may enable optimized contact structures 130 and smaller epi bodies 110 (e.g., minimal bodies 110 that couple nanoribbons 120 with contact structures 130).

Source or drain bodies 110A, 110B may be of different materials, for example, to improve performance in complementary transistor structures 101A, 101B. In many embodiments, structures 101A are n-type transistor structures 101A, and bodies 110A are predominantly silicon. In many embodiments, structures 101B are p-type transistor structures 101B, and bodies 110B include silicon. In some such embodiments, bodies 110B include germanium.

Spacers 147, 148 (as illustrated at views 102, 103, 104) are isolation structures, e.g., of insulator material (such as a low-k dielectric material), adjacent gate electrodes 125. Spacers 148 provide isolation between electrodes 125 and bodies 110. Spacers 147 provide isolation between electrodes 125 and bodies 110 and contact structures 130 over bodies 110.

As shown in views 103 and 104, nanoribbons 120 extend through gate electrodes 125, which are metallization structures that may electrostatically control the conduction of transistor structures 101 through transistor channels of nanoribbons 120. Gate electrodes 125 in transistor structures 101A, 101B and over stacks 121A, 121B may be different or substantially similar (e.g., the same), for example, having metal layers of different quantity and quality. For example, electrodes 125 in structures 101A, 101B may include different workfunction metals (WFM), such as WFM liner layers. Gate electrodes 125 may include liner (e.g., barrier and/or seed) and fill (or bulk) metals, WFMs and other “metals,” etc., some or all of which may include single elements (such as tungsten) or multiple elements, both metals (e.g., titanium, tantalum, aluminum, etc.) and nonmetals (e.g., carbon, nitrogen, etc.).

In many conventional IC devices with strained transistor channels, transistors depend on strain generation from gate metals. The use of dielectric materials 141, 142 (e.g., to generate channel strain) may enable simpler fabrication of electrodes 125 or the employment of materials (e.g., metals) optimized for characteristics (such as electrical characteristics) other than generating complementary (e.g., tensile and/or compressive) stresses. In many embodiments, a single gate electrode 125 is over and between nanoribbons 120A in a first stack 121A and over and between nanoribbons 120B in a second stack 121B. In many embodiments, a single gate electrode 125 includes a metal (e.g., tungsten) over and between both nanoribbons 120A, 120B in first and second stacks 121A, 121B. In many embodiments, a first gate electrode 125 is over and between nanoribbons 120A in a first stack 121A, and a second gate electrode 125 is over and between nanoribbons 120B in a stack 121B. In many such embodiments, the first gate electrode 125 includes a metal (e.g., tungsten) over and between nanoribbons 120A in the first stack 121A, and the second gate electrode 125 includes the same metal (e.g., tungsten) over and between nanoribbons 120B in the second stack 121B. For example, in some embodiments, first and second gate electrodes 125 are fabricated concurrently (e.g., together and of a same metal, for example, tungsten), before being separated by a gate cut dielectric structure 126.

Gate electrodes 125 may be part of gate structures that include gate dielectric layers 123 (e.g., high-k gate dielectric layers 123), which may be of different (or substantially similar) quantity and quality in transistor structures 101A, 101B. Gate dielectric layers 123 insulate channel regions of nanoribbons 120A, 120B from electrodes 125. Nanoribbons 120 may also have other dielectric layers (such as passivation layers on nanoribbons 120A, 120B) insulating channel regions of nanoribbons 120A, 120B from electrodes 125. Dielectric layers 123 are on spacers 147, 148. Gate vias (not shown) through dielectric layers 124 on and over electrodes 125 may couple electrodes 125 to interconnect layers and networks (not shown), e.g., over transistor structures 101.

Substrate 199 may include any suitable material or materials. Substrate 199 may be an IC substrate, such as an IC die or wafer. In some examples, the substrate may include monocrystalline silicon (including silicon on insulator (SOI)), polycrystalline silicon, germanium, silicon germanium, a III-V alloy material (e.g., gallium arsenide), a silicon carbide (e.g., SiC), a sapphire (e.g., Al₂O₃), or any combination thereof. Substrate 199 may also include semiconductor materials, metals, dielectrics, dopants, and other materials commonly found in semiconductor substrates. Substrate 199 may refer specifically to a base material (for example, a thick base or layer of semiconductor material) that other materials (such as metals and dielectrics) are built up on. In some contexts, substrate 199 may refer to a base material layer and any build-up layers, etc., over the base. Transistor structures 101 may be over a dielectric layer over other (e.g., semiconductor) materials.

FIG. 1B shows plan view 102 (e.g., from FIG. 1A, for reference), as well as profile view 105 with y-z viewing plane D-D′ (orthogonal to x-z viewing planes B-B′ and C-C′ of views 103, 104). Viewing plane D-D′ is orthogonally through stacks 121A, 121B (e.g., stacks 121A-b, 121B-b) of nanoribbons 120A, 120B (e.g., nanoribbons 120A1b-120A4b,120B1b-120B4b) in transistor structures 101A, 101B, respectively. In exemplary embodiments of view 105, transistor structures 101A are n-type structures 101A, and transistor structures 101B are p-type structures 101B.

Nanoribbons 120A (e.g., nanoribbons 120A1b-120A4b in view 105) in each stack 121A (e.g., stack 121A-b in view 105) have substantially equal lattice constants, which are substantially different than a lattice constant of substrate 199, e.g., under or below stacks 121A. In exemplary embodiments of FIG. 1B, n-type structures 101A are subject to tensile stress, and semiconductor nanoribbons 120A in stacks 121A have a crystalline lattice with a larger lattice constant than a crystalline lattice of substrate 199 under or below stacks 121A. In exemplary embodiments of FIG. 1B, stacks 121A of nanoribbons 120A in transistor structures 101A are between and coupled with source and drain semiconductor bodies 110A (as illustrated in view 103) having an n-type dopant. Each body 110A is in contact with a metallization structure 130.

Nanoribbons 120B (e.g., nanoribbons 120B1b-120B4b in view 105) in each stack 121B (e.g., stack 121B-b in view 105) have substantially equal lattice constants, which are substantially different than a lattice constant of substrate 199, e.g., under or below stacks 121B. In exemplary embodiments of FIG. 1B, p-type structures 101B are subject to compressive stress, and semiconductor nanoribbons 120B in stacks 121B have a crystalline lattice with a smaller lattice constant than a crystalline lattice of substrate 199 under or below stacks 121B. In exemplary embodiments of FIG. 1B, stacks 121B of nanoribbons 120B in transistor structures 101B are between and coupled with source and drain semiconductor bodies 110B (as shown in view 104) having a p-type dopant. Each body 110B is in contact with a metallization structure 130. In many embodiments, first metallization structures 130 on source and drain semiconductor bodies 110A in transistor structures 101A include a same composition as second metallization structures 130 on source and drain semiconductor bodies 110B in transistor structures 101B. The use of the same materials (e.g., optimized for conductivity) may be enabled by the deployment of dielectric materials 141, 142.

In exemplary embodiments of view 105, a single gate electrode 125 is over and between nanoribbons 120A in stack 121A and over and between nanoribbons 120B in stack 121B. Gate electrode 125 includes a metal (e.g., tungsten) over and between both nanoribbons 120A, 120B in first and second stacks 121A, 121B.

In FIG. 1C (as in FIG. 1A), view 102 shows groups of transistor structures 101A, 101B aligned on separate centerplanes B-B′ and C-C′, respectively, which are viewing planes B-B′ and C-C′ of views 103, 104. Source and drain contact structures 130 of structures 101A, 101B are also aligned on respective centerplanes B-B′ and C-C′. Notably, separate source and drain bodies 110A, 110B are in each trench 115, and contact structures 130 between corresponding stacks 121A, 121B (as shown at views 103, 104) extend between corresponding source and drain bodies 110A, 110B. Gate electrodes 125 are over (and between) corresponding nanoribbons 120A, 120B in stacks 121A, 121B, between source and drain contact structures 130 (as shown at views 103, 104). Nanoribbons 120A, 120B and stacks 121A, 121B extend in the x-directions through electrodes 125, as shown at views 103, 104. Spacers 147 are between electrodes 125 and contact structures 130, e.g., providing electrical isolation.

Bodies 110 are on each side of (and do not span) trenches 115. In the exemplary embodiments of FIG. 1C, a pair of bodies 110 bookend each contact structure 130, with a body 110 on each side of each contact structure 130, e.g., merged separately on the nanoribbons 120 of each stack 121, but not merged or continuous between different stacks 121. In each trench 115, contact structure 130 is in contact with a pair of first and second bodies 110 between stacks 121 of nanoribbons 120, a first of the semiconductor bodies 110 is coupled with the first stack 121 of nanoribbons 120, and a second of the semiconductor bodies 110 is coupled with the second stack 121 of nanoribbons 120. In each trench 115, structure 130 is coupled with each stack 121 of nanoribbons 120 by the respective first or second body 110 on that side of structure 130.

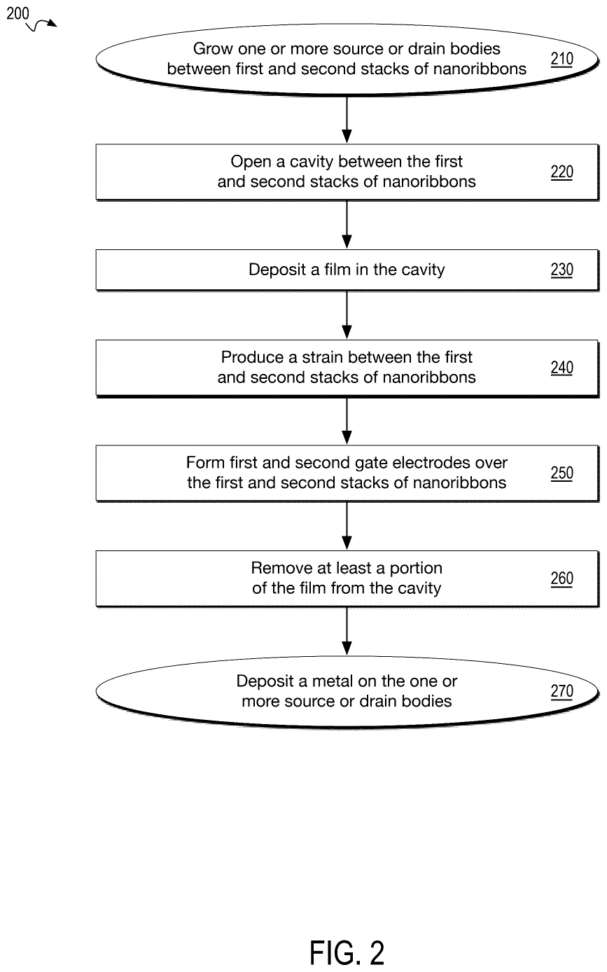

FIG. 2 is a flow chart of methods 200 for straining transistor channels with sacrificial films, in accordance with some embodiments. Methods 200 include operations 210-270. Some operations shown in FIG. 2 are optional. Additional operations may be included. FIG. 2 shows an example sequence, but the operations can be done in other orders as well, and some operations may be omitted. Some operations can also be performed multiple times before other operations are performed. For example, epitaxial bodies may be grown before and/or after straining nanoribbon channels, and multiple sacrificial films may be deposited before producing strains or forming gate electrodes between nanoribbons. Some operations may be included within other operations so that the number of operations illustrated FIG. 2 is not a limitation of the methods 200.

FIGS. 3A, 3B, 3C, 3D, 3E, and 3F illustrate cross-sectional plan and profile views of an IC device having strain-generating dielectric materials 141, 142 adjacent strained channels in nanoribbons 120A, 120B in transistor structures 101A, 101B, at various stages of manufacture, in accordance with some embodiments. FIGS. 3A-3F show possible examples of intermediate structures during an embodiment of a practice of methods 200 of FIG. 2. Plan views 302 are over trench 115 between spacers 147. Profile views 303 are through stacks 121A, 121B of nanoribbons 120A, 120B. Profile views 304 are of trench 115 between spacers 147.

Returning to FIG. 2, methods 200 begin at operation 210 with growing one or more source or drain bodies, for example, in a trench between nanoribbon stacks over a substrate. A source or drain body may be grown by any suitable means and of any suitable material(s), such as one or more semiconductor materials. In many embodiments, many source or drain bodies are grown concurrently, for example, epitaxially, off ends of nanoribbons in vertical stacks. The nanoribbons may be vertically aligned in stacks over a substrate, and the stacks may be aligned in a row (e.g., on a shared centerplane axis) with one or more trenches (e.g., orthogonally) between aligned stacks.

The one or more source or drain bodies grown may be much as described of bodies 110A or 110B at FIG. 1A (for example, being of semiconductor material), but some of the final characteristics of bodies 110 described at FIG. 1A, etc., may only be attained following subsequent processing. The substrate the bodies may be grown over may be much as described of substrate 199 at FIG. 1A, and the nanoribbons and stacks over the substrate may be much as described of nanoribbons 120 and stacks 121 at FIG. 1A.

The source or drain body (or bodies) may be grown early in the process or later, e.g., after other operations (including, for example, both early and later in the process). During methods 200 (e.g., at operation 240), a strain will be produced in a pair of nanoribbon stacks, for example, by an expansive or contractive stress in a trench between the pair of stacks (compressing or tensioning the nanoribbons, respectively). In some embodiments, the one or more source or drain bodies are grown following the straining of the nanoribbons, e.g., before contacting the source-drain bodies. In other embodiments, the one or more source or drain bodies aid the straining of the nanoribbons, e.g., as rigid bodies for jointly and concurrently compressing or tensioning a stack of nanoribbons in parallel. For example, epi bodies may be grown on both sides of a trench and each merge between the nanoribbons on that side, and the compressive or tensile stress may exert strain on all of the nanoribbons in a stack through the rigid epi body to that side of the trench and strain source.

In many embodiments, the source or drain bodies are grown into a merged, unitary body, e.g., coupled with all of the nanoribbons in both of a pair of aligned and adjacent stacks, spanning a trench between the pair of stacks. A unitary body between stacks may subsequently be split to make space for the development of a compressing or tensioning force. In some embodiments, a first source or drain body is grown on a first nanoribbon stack and a second source or drain body is grown on a second nanoribbon stack across a trench from the first stack. For example, a pair of source or drain bodies may be grown in each trench between stacks, e.g., with a separate, merged body on each side of the trench coupling the nanoribbons within each stack. In some embodiments, a merged source or drain body is grown on each side of the trench, coupling the nanoribbons within each stack, but only merged (e.g., continuous) on a floor of the trench, with a space available between the stacks. In embodiments with source-drain bodies grown early in methods 200 (e.g., before straining nanoribbon channels), further growth of source-drain bodies may also be done at a later operation, for example, to merge or improve contacting of source-drain bodies.

Growing the one or more source or drain bodies in a trench between first and second aligned nanoribbon stacks may also grow at least a second source or drain body on and between third and fourth nanoribbon stacks, e.g., in the same trench. For example, many parallel rows of aligned nanoribbon stacks may be crossed by orthogonal trenches between aligned pairs of stacks (such as the first and second and the third and fourth stacks). In many embodiments, at least some adjacent pairs of nanoribbon stacks split by the same trench are of complementary conductivity types. For example, a trench may split n-type first and second nanoribbon stacks and adjacent p-type third and fourth nanoribbon stacks. The complementary stacks and nanoribbons may be substantially similar (e.g., compositionally) before the complementary source or drain bodies are grown. Complementary source or drain bodies may be grown sequentially (e.g., not concurrently) to provide different body compositions (e.g., at least dopant differences).

FIG. 3A shows source or drain bodies 110A, 110B in trench 115 between dummy gates 325 and spacers 147 in a workpiece or IC device 100, in accordance with some embodiments, for example, following a performance of growing operation 210. Overhead plan view 302 illustrates bodies 110A, 110B in trench 115 between dummy gates 325 and spacers 147. Source or drain bodies 110A, 110B are dashed to indicate their positions behind the viewing plane, in trench 115. Profile view 303 shows stacks 121A, 121B of nanoribbons 120A, 120B and sacrificial layers 320A, 320B extending (e.g., in the x-directions) through dummy gate 325. Source or drain bodies 110A, 110B are dashed to indicate their position behind the viewing plane and dummy gate 325. Profile view 304 illustrates body 110A (in front of obscured body 110B) in trench 115 between dummy gates 325 and spacers 147. Source or drain body 110A is dashed to indicate the position of body 110A behind the viewing plane, in trench 115. In exemplary embodiments of FIG. 3A, bodies 110A, 110B are unitary bodies 110A, 110B, merged and continuous between the entirety of stacks 121 and nanoribbons 120.

Returning to FIG. 2, methods 200 continue by opening a cavity between the first and second nanoribbon stacks at operation 220. The cavity may be opened by any suitable means, such as an anisotropic plasma etch. The cavity may be the trench between the nanoribbon stacks (for example, in embodiments where the one or more source or drain bodies are grown following the straining of the nanoribbons), and the opening of the cavity may be by etching through fins of the nanoribbons, e.g., by etching the fins into shorter nanoribbon-stack segments. In some embodiments, the cavity is opened by etching into (or through) a merged source or drain body coupled with and between a pair of nanoribbon stacks. In some such embodiments, opening the cavity etches into the source or drain body to below a lowest nanoribbon in a first adjacent nanoribbon stack and below a lowest nanoribbon in a second adjacent nanoribbon stack (e.g., completely opening the cavity between the pair of adjacent stacks).

Opening the cavity between the first and second nanoribbon stacks, for example, by a downward etch, opens the cavity between adjacent third and fourth nanoribbon stacks, in many embodiments. Whether forming the trench, splitting a semiconductor body, etc., a single etch orthogonal to aligned nanoribbons in one pair of stacks may also etch through a second pair of nanoribbons stacks.

FIG. 3B illustrates cavities 315 into or through etched-down source or drain bodies 110A, 110B in trench 115 between dummy gates 325 and spacers 147 in device 100, in accordance with some embodiments, for example, following a performance of opening operation 220. Plan view 302 shows bodies 110A, 110B in trench 115 between dummy gates 325 and spacers 147. Cavities 315 are into bodies 110 and within trench 115. Profile view 303 illustrates stacks 121A, 121B of nanoribbons 120A, 120B and sacrificial layers 320A, 320B. Multiple dashed outlines (e.g., at different depths) of source or drain bodies 110A, 110B coupled with nanoribbons 120A, 120B indicate the etched-down borders, e.g., adjacent nanoribbons 120 and in a saddle in the middle of trench 115. Profile view 304 shows cavity 315 in etched-down body 110a in Trench 115.

Returning to FIG. 2, methods 200 continue at operation 230 with depositing a film in the cavity. The film may be deposited by any suitable means and of any suitable material(s), such as dielectric materials that will change volume upon further processing. In many embodiments, at least two different films are deposited in the cavity. In some such embodiments, a first film is deposited in the cavity between first and second nanoribbon stacks (e.g., separated by the cavity), and a second film is deposited in the cavity between adjacent third and fourth nanoribbon stacks. For example, a contractive, first film may be deposited in a cavity between n-type nanoribbon stacks to provide tensile strain, and an expansive, second film may be deposited in a cavity between p-type nanoribbon stacks to provide compressive strain. The deposited films may be much as described of materials 141, 142 at FIG. 1A. The films may be deposited by a CVD (chemical vapor deposition) or ALD (atomic layer deposition), spin coating, or any other suitable means.

In many embodiments, a liner layer (e.g., of dielectric material) is conformally deposited in the cavity before the strain-producing film(s), and the one or more strain-producing films are deposited in the cavity over (e.g., on) the liner layer. In some embodiments, multiple liner layers are deployed, for example, a first liner layer conformally over a trench cavity before either strain-producing film is deposited on the first liner layer and then a second liner layer after a first strain-producing film is deposited (e.g., to protect the first strain-producing film from a second strain-producing film deposited on and in the second liner layer). Similarly, a liner layer may be deposited after (e.g., over) a strain-producing film (e.g., to provide an etch selectivity or protect an adjacent structure or material from the strain-producing film). The liner layers may provide etch selectivities, which may aid in the subsequent removal of one or more of the one or more strain-producing films. One or more of the deposited films may be oxidative, and the liner layer may provide protection from possible oxidation. The liner layer may be much as described of dielectric layer 143 at FIG. 1A, for example, being or including a nitride.

FIG. 3C shows strain-producing materials 141, 142 in trench 115 in device 100, in accordance with some embodiments, for example, following a performance of depositing operation 230. View 302 illustrates materials 141, 142 in a first liner layer 143 and trench 115 between dummy gates 325 and spacers 147. Material 142 and a second liner layer 143 are in the first liner layer 143. In some embodiments, material 141 and an additional liner layer 143 are in the first liner layer 143. Complementary materials 141, 142 are over bodies 110A, 110B, e.g., with strain-producing material 141 within a cavity in body 110A and strain-producing material 142 within a cavity in body 110B. View 303 shows stacks 121A, 121B of nanoribbons 120A, 120B and sacrificial layers 320A, 320B. View 304 illustrates material 141 and liner layer 143 filling trench 115. In some embodiments, an additional liner layer 143 is over one or both of materials 141, 142 (e.g., in the positive z-direction, over a top of view 304 and in front of the viewing plane of view 302).

Returning to FIG. 2, methods 200 continue by producing a strain in the first and second nanoribbon stacks at operation 240. The strain may be produced by any suitable means and may be tensile or compressive. The strain may be produced by the film deposited in the cavity, between the nanoribbon stacks. In many embodiments, a first strain is produced in the first and second nanoribbon stacks, and a complementary second strain is produced in adjacent third and fourth nanoribbon stacks. The strain may be produced by further processing of the film after deposition in the cavity. For example, a tensile first strain may be produced in first and second n-type nanoribbon stacks by a curing (and consequent contraction) of an uncured oxide film deposited (e.g., spun on) between the n-type nanoribbon stacks. A compressive second strain may be produced in third and fourth p-type nanoribbon stacks by an oxidation (and consequent expansion) of an amorphous-silicon film deposited between the p-type nanoribbons.

Returning to FIG. 2, methods 200 continue at operation 250 by forming first and second gate electrodes over the first and second nanoribbon stacks. In many embodiments, one or more gate electrodes are formed over adjacent third and fourth nanoribbon stacks, e.g., concurrently with the first and second gate electrodes over the first and second nanoribbon stacks. In some embodiments, the one or more gate electrodes over the adjacent third and fourth nanoribbon stacks are shared with the first and second nanoribbon stacks. For example, a first gate electrode may be over the first and third nanoribbon stacks on a first side of a trench, and the second gate electrode may be over the second and fourth nanoribbon stacks on an opposing, second side of the trench.

Forming the gate electrodes may hold or memorize the strain in the respective nanoribbon channels and, for example, retain the strain after subsequent removal of some or all of the strain-producing film material(s). The first and second gate electrodes may be formed by any suitable means and of any suitable material(s). In many embodiments, the gate electrodes are formed of one or more metals. The gate electrodes may be much as described of electrodes 125 at FIG. 1A. In many embodiments, the first and second gate electrodes are formed by removing dummy gates from over the nanoribbon stacks (e.g., at least one dummy gate on each side of the trench between the stacks), and (while the nanoribbons are strained) by forming a gate structure on the strained nanoribbons. Besides removing the dummy gates, sacrificial material layers may be removed from between the nanoribbons. The gate structure may then be formed on and between the strained nanoribbons by conformally depositing a gate dielectric layer on the nanoribbon channels and by depositing a metal (gate electrode) onto the gate dielectric layer around the nanoribbon channels.

FIG. 3D illustrates materials 141, 142 in trench 115 between gate electrodes 125 in device 100, in accordance with some embodiments, for example, following a performance of producing and forming operations 240 and 250. View 302 shows materials 141, 142 over bodies 110A, 110B and in liner layer 143 and trench 115 between spacers 147 and dielectric layers 124 (on and over gate electrodes 125). View 303 illustrates nanoribbons 120A, 120B extending (e.g., in the x-directions) through gate electrode 125, e.g., with electrode 125 between nanoribbons 120A, 120B. View 304 shows material 141 and liner layer 143 filling trench 115 between gate electrodes 125.

Returning to FIG. 2, methods 200 continue at operation 260 with removing at least a portion of the film from the cavity. Removing the film portions may expose source or drain bodies in the trench and cavities in or over the bodies. The removed film portion(s) may be sacrificial material that may then be replaced by epitaxially grown source or drain bodies and/or metallization contact structures. The film material may be removed by any suitable means, such as a patterned etch, which may be at least somewhat selective. For example, in many embodiments, the etch is stopped by a liner layer deposited at operation 230. An etch (selective or otherwise) may remove, e.g., one or both of a pair of tensile and compressive films.

FIG. 3E shows cavity 315 over bodies 110A, 110B in trench 115, between spacers 147 and gate electrodes 125 in device 100, in accordance with some embodiments, for example, following a performance of removing operation 260. View 302 illustrates retained materials 141, 142 to either side of cavity 315 and exposed bodies 110A, 110B in trench 115 between spacers 147. View 303 shows nanoribbons 120A, 120B extending through gate electrode 125. View 304 illustrates material 141 and liner layer 143 filling trench 115 between gate electrodes 125.

Returning to FIG. 2, methods 200 continue by depositing a metal on the one or more source or drain bodies at operation 270. The metal may be any suitable metal and may be deposited by any suitable means. The metal may be one or more metals and may be deposited by a CVD and/or ALD, etc. The metal may be deposited in the cavity (e.g., trench) and may replace the removed portion of the film, for example, on an exposed source or drain body. A dielectric material may be patterned in the cavity, and the metal may be deposited within the patterned dielectric material. The deposited metal may form one or more contact structures 130 as described at FIG. 1A, e.g., extending down between stacks of nanoribbons.

FIG. 3F illustrates contact structures 130 in and through dielectric structure 144 in trench 115 in IC device 100, in accordance with some embodiments, for example, following a performance of depositing operation 270. View 302 shows contact structures 130 and dielectric structure 144 in trench 115 between spacers 147. In some embodiments, each contact structure 130 is in a separate dielectric structure 144, and materials 141, 142 and layers 143 are between the pairs of separate structures 130, 144. View 303 illustrates gate via 327 contacting gate electrode 125 through dielectric layer 124. View 304 shows material 141 and liner layer 143 filling trench 115 between gate electrodes 125, e.g., adjacent source or drain body 110A (not shown).

IC device 100 may include or be coupled to a substrate or other host component 399. Host component 399 may be a package substrate, an interposer, an IC die, etc. For example, substrate 199 may be an IC die that includes transistor structures 101, substrate 199 may be coupled (e.g., soldered or otherwise bonded) to host component 399, and transistor structures 101 may be coupled to a power supply (not shown) through host component 399.

Host component 399 is a planar platform and may include dielectric and metallization structures. Host component 399 mechanically supports and electrically couples one or more IC devices 100. At least one side of host component 399 includes substrate interconnect interfaces for bonding to one or more IC devices 100. IC device 100 may be direct bonded, e.g., hybrid bonded, to host component 399 or otherwise bonded, e.g., by optional solder bumps. The opposite side of host component 399 may include similar interfaces, e.g., copper pads for socketing and/or solder bumps for bonding device 100 to a host component, such as a printed circuit board (PCB). Host component 399 may be any host component with substrate interconnect interfaces, such as a package host component 399 or interposer, etc. Host component 399 may itself be a die. In many embodiments, host component 399 includes organic dielectric(s), such as a resin or other polymer, between metallization layers.

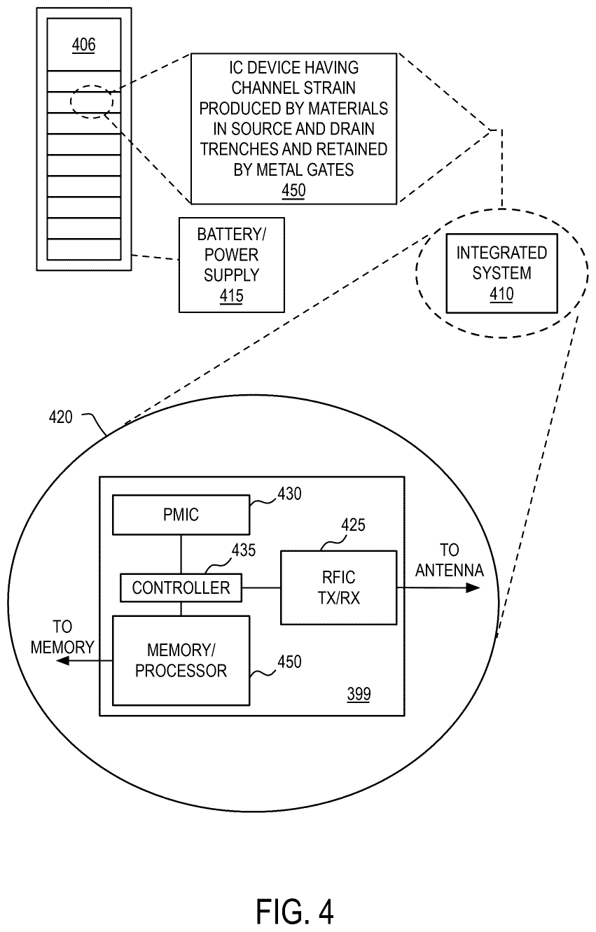

FIG. 4 illustrates a diagram of an example data server machine 406 employing an IC device having transistor channels with strain produced by materials in source and drain trenches and retained by metal gate electrodes, in accordance with some embodiments. Server machine 406 may be any commercial server, for example, including any number of high-performance computing platforms disposed within a rack and networked together for electronic data processing, which in the exemplary embodiment includes one or more devices 450 having transistor channels with strain produced by materials in source and drain trenches and retained by metal gate electrodes.

Also as shown, server machine 406 includes a battery and/or power supply 415 to provide power to devices 450, and to provide, in some embodiments, power delivery functions such as power regulation. Devices 450 may be deployed as part of a package-level integrated system 410. Integrated system 410 is further illustrated in the expanded view 420. In the exemplary embodiment, devices 450 (labeled “Memory/Processor”) includes at least one memory chip (e.g., random-access memory (RAM)), and/or at least one processor chip (e.g., a microprocessor, a multi-core microprocessor, or graphics processor, or the like) having the characteristics discussed herein. In an embodiment, device 450 is a microprocessor including a static RAM (SRAM) cache memory. As shown, device 450 may be an IC device having transistor channels with strain produced by materials in source and drain trenches and retained by metal gate electrodes, as discussed herein. Device 450 may be further coupled to (e.g., communicatively coupled to) a board, an interposer, or other substrate or host component 399 along with, one or more of a power management IC (PMIC) 430, RF (wireless) IC (RFIC) 425 including a wideband RF (wireless) transmitter and/or receiver (TX/RX) (e.g., including a digital baseband and an analog front-end module further includes a power amplifier on a transmit path and a low noise amplifier on a receive path), and a controller 435 thereof. In some embodiments, RFIC 425, PMIC 430, controller 435, and device 450 include having transistor channels with strain produced by materials in source and drain trenches and retained by metal gate electrodes.

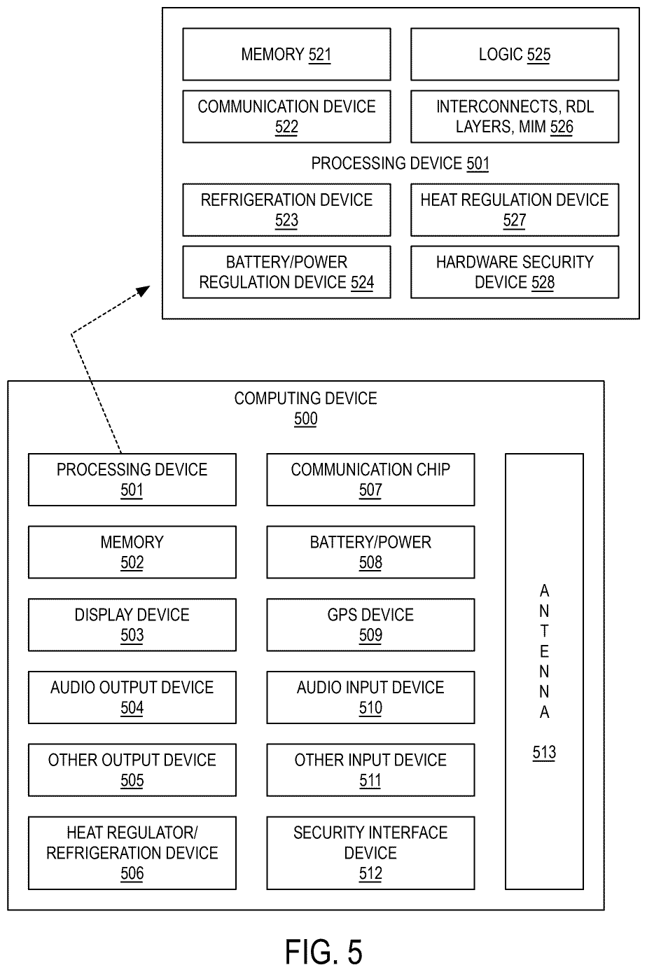

FIG. 5 is a block diagram of an example computing device 500, in accordance with some embodiments. For example, one or more components of computing device 500 may include any of the devices or structures discussed herein. A number of components are illustrated in FIG. 5 as being included in computing device 500, but any one or more of these components may be omitted or duplicated, as suitable for the application. In some embodiments, some or all of the components included in computing device 500 may be attached to one or more printed circuit boards (e.g., a motherboard). In some embodiments, various ones of these components may be fabricated onto a single system-on-a-chip (SoC) die. Additionally, in various embodiments, computing device 500 may not include one or more of the components illustrated in FIG. 5, but computing device 500 may include interface circuitry for coupling to the one or more components. For example, computing device 500 may not include a display device 503, but may include display device interface circuitry (e.g., a connector and driver circuitry) to which display device 503 may be coupled. In another set of examples, computing device 500 may not include an audio output device 504, other output device 505, global positioning system (GPS) device 509, audio input device 510, or other input device 511, but may include audio output device interface circuitry, other output device interface circuitry, GPS device interface circuitry, audio input device interface circuitry, audio input device interface circuitry, to which audio output device 504, other output device 505, GPS device 509, audio input device 510, or other input device 511 may be coupled.

Computing device 500 may include a processing device 501 (e.g., one or more processing devices). As used herein, the term “processing device” or “processor” indicates a device that processes electronic data from registers and/or memory to transform that electronic data into other electronic data that may be stored in registers and/or memory. Processing device 501 may include a memory 521, a communication device 522, a refrigeration device 523, a battery/power regulation device 524, logic 525, interconnects 526 (i.e., optionally including redistribution layers (RDL) or metal-insulator-metal (MIM) devices), a heat regulation device 527, and a hardware security device 528.

Processing device 501 may include one or more digital signal processors (DSPs), application-specific ICs (ASICs), central processing units (CPUs), graphics processing units (GPUs), cryptoprocessors (specialized processors that execute cryptographic algorithms within hardware), server processors, or any other suitable processing devices.

Computing device 500 may include a memory 502, which may itself include one or more memory devices such as volatile memory (e.g., dynamic random-access memory (DRAM)), nonvolatile memory (e.g., read-only memory (ROM)), flash memory, solid state memory, and/or a hard drive. In some embodiments, memory 502 includes memory that shares a die with processing device 501. This memory may be used as cache memory and may include embedded dynamic random-access memory (eDRAM) or spin transfer torque magnetic random-access memory (STT-MRAM).

Computing device 500 may include a heat regulation/refrigeration device 506. Heat regulation/refrigeration device 506 may maintain processing device 501 (and/or other components of computing device 500) at a predetermined low temperature during operation.

In some embodiments, computing device 500 may include a communication chip 507 (e.g., one or more communication chips). For example, the communication chip 507 may be configured for managing wireless communications for the transfer of data to and from computing device 500. The term “wireless” and its derivatives may be used to describe circuits, devices, systems, methods, techniques, communications channels, etc., that may communicate data through the use of modulated electromagnetic radiation through a nonsolid medium. The term does not imply that the associated devices do not contain any wires, although in some embodiments they might not.

Communication chip 507 may implement any of a number of wireless standards or protocols, including but not limited to Institute for Electrical and Electronic Engineers (IEEE) standards including Wi-Fi (IEEE 802.11 family), IEEE 802.16 standards (e.g., IEEE 802.16-2005 Amendment), Long-Term Evolution (LTE) project along with any amendments, updates, and/or revisions (e.g., advanced LTE project, ultramobile broadband (UMB) project (also referred to as “3GPP2”), etc.). IEEE 802.16 compatible Broadband Wireless Access (BWA) networks are generally referred to as WiMAX networks, an acronym that stands for Worldwide Interoperability for Microwave Access, which is a certification mark for products that pass conformity and interoperability tests for the IEEE 802.16 standards. Communication chip 507 may operate in accordance with a Global System for Mobile Communication (GSM), General Packet Radio Service (GPRS), Universal Mobile Telecommunications System (UMTS), High Speed Packet Access (HSPA), Evolved HSPA (E-HSPA), or LTE network. Communication chip 507 may operate in accordance with Enhanced Data for GSM Evolution (EDGE), GSM EDGE Radio Access Network (GERAN), Universal Terrestrial Radio Access Network (UTRAN), or Evolved UTRAN (E-UTRAN). Communication chip 507 may operate in accordance with Code Division Multiple Access (CDMA), Time Division Multiple Access (TDMA), Digital Enhanced Cordless Telecommunications (DECT), Evolution-Data Optimized (EV-DO), and derivatives thereof, as well as any other wireless protocols that are designated as 3G, 4G, 5G, and beyond. Communication chip 507 may operate in accordance with other wireless protocols in other embodiments. Computing device 500 may include an antenna 513 to facilitate wireless communications and/or to receive other wireless communications (such as AM or FM radio transmissions).

In some embodiments, communication chip 507 may manage wired communications, such as electrical, optical, or any other suitable communication protocols (e.g., the Ethernet). As noted above, communication chip 507 may include multiple communication chips. For instance, a first communication chip 507 may be dedicated to shorter-range wireless communications such as Wi-Fi or Bluetooth, and a second communication chip 507 may be dedicated to longer-range wireless communications such as GPS, EDGE, GPRS, CDMA, WiMAX, LTE, EV-DO, or others. In some embodiments, a first communication chip 507 may be dedicated to wireless communications, and a second communication chip 507 may be dedicated to wired communications.

Computing device 500 may include battery/power circuitry 508. Battery/power circuitry 508 may include one or more energy storage devices (e.g., batteries or capacitors) and/or circuitry for coupling components of computing device 500 to an energy source separate from computing device 500 (e.g., AC line power).

Computing device 500 may include a display device 503 (or corresponding interface circuitry, as discussed above). Display device 503 may include any visual indicators, such as a heads-up display, a computer monitor, a projector, a touchscreen display, a liquid crystal display (LCD), a light-emitting diode display, or a flat panel display, for example.

Computing device 500 may include an audio output device 504 (or corresponding interface circuitry, as discussed above). Audio output device 504 may include any device that generates an audible indicator, such as speakers, headsets, or earbuds, for example.

Computing device 500 may include an audio input device 510 (or corresponding interface circuitry, as discussed above). Audio input device 510 may include any device that generates a signal representative of a sound, such as microphones, microphone arrays, or digital instruments (e.g., instruments having a musical instrument digital interface (MIDI) output).

Computing device 500 may include a GPS device 509 (or corresponding interface circuitry, as discussed above). GPS device 509 may be in communication with a satellite-based system and may receive a location of computing device 500, as known in the art.

Computing device 500 may include other output device 505 (or corresponding interface circuitry, as discussed above). Examples of the other output device 505 may include an audio codec, a video codec, a printer, a wired or wireless transmitter for providing information to other devices, or an additional storage device.

Computing device 500 may include other input device 511 (or corresponding interface circuitry, as discussed above). Examples of the other input device 511 may include an accelerometer, a gyroscope, a compass, an image capture device, a keyboard, a cursor control device such as a mouse, a stylus, a touchpad, a bar code reader, a Quick Response (QR) code reader, any sensor, or a radio frequency identification (RFID) reader.

Computing device 500 may include a security interface device 512. Security interface device 512 may include any device that provides security measures for computing device 500 such as intrusion detection, biometric validation, security encode or decode, access list management, malware detection, or spyware detection.

Computing device 500, or a subset of its components, may have any appropriate form factor, such as a hand-held or mobile computing device (e.g., a cell phone, a smart phone, a mobile internet device, a music player, a tablet computer, a laptop computer, a netbook computer, a personal digital assistant (PDA), an ultramobile personal computer, etc.), a desktop computing device, a server or other networked computing component, a printer, a scanner, a monitor, a set-top box, an entertainment control unit, a vehicle control unit, a digital camera, a digital video recorder, or a wearable computing device.

The subject matter of the present description is not necessarily limited to specific applications illustrated in FIGS. 1A-5. The subject matter may be applied to other deposition applications, as well as any appropriate manufacturing application, as will be understood to those skilled in the art.

The following examples pertain to further embodiments, and specifics in the examples may be used anywhere in one or more embodiments.

In one or more first embodiments, an apparatus includes a first stack of nanoribbons in a first transistor structure over a substrate, the nanoribbons in the first stack including first lattice constants, the substrate including a second lattice constant, the first and second lattice constants substantially different, a second stack of nanoribbons in a second transistor structure over the substrate, the first and second stacks of nanoribbons aligned and extending in a direction, the nanoribbons in the second stack including third lattice constants approximately equal to the first lattice constants, and a metallization structure in the first and second transistor structures, the metallization structure coupled with the first and second stacks of nanoribbons, the metallization structure between an uppermost nanoribbon of the first stack of nanoribbons and an uppermost nanoribbon of the second stack of nanoribbons.

In one or more second embodiments, further to the first embodiments, a semiconductor body is in contact with the metallization structure, the semiconductor body is coupled with the first or second stacks of nanoribbons, the semiconductor body includes an n-type dopant, and the first and third lattice constants are greater than the second lattice constant.

In one or more third embodiments, further to the first or second embodiments, a semiconductor body is in contact with the metallization structure, the semiconductor body is coupled with the first or second stacks of nanoribbons, the semiconductor body includes a p-type dopant, and the second lattice constant is greater than the first and third lattice constants.

In one or more fourth embodiments, further to the first through third embodiments, the metallization structure is a first metallization structure in a trench between the first and second stacks of nanoribbons, a third stack of nanoribbons in a third transistor structure is over the substrate, the nanoribbons in the third stack including fourth lattice constants, a fourth stack of nanoribbons in a fourth transistor structure is over the substrate, the third and fourth stacks of nanoribbons aligned and extending in the direction, the nanoribbons in the second stack including fifth lattice constants, and a second metallization structure in the third and fourth transistor structures is in the trench, the second metallization structure coupled with the third and fourth stacks of nanoribbons, the second metallization structure between an uppermost nanoribbon of the third stack of nanoribbons and an uppermost nanoribbon of the fourth stack of nanoribbons, the first and third lattice constants are greater than the second lattice constant, and the second lattice constant is greater than the fourth and fifth lattice constants.

In one or more fifth embodiments, further to the first through fourth embodiments, a first semiconductor body is in contact with the first metallization structure, the first semiconductor body is coupled with the first or second stacks of nanoribbons, the first semiconductor body includes an n-type dopant, a second semiconductor body is in contact with the second metallization structure, the second semiconductor body is coupled with the third or fourth stacks of nanoribbons, and the second semiconductor body includes a p-type dopant.

In one or more sixth embodiments, further to the first through fifth embodiments, the first and second metallization structures include a same composition.

In one or more seventh embodiments, further to the first through sixth embodiments, a third metallization structure includes a metal, and the metal is over and between the nanoribbons in the first stack of nanoribbons and over and between the nanoribbons in the third stack of nanoribbons.

In one or more eighth embodiments, further to the first through seventh embodiments, the first metallization structure is in contact with first and second semiconductor bodies between the first and second stacks of nanoribbons, the first and second semiconductor bodies including an n-type dopant, the first semiconductor body is coupled with the first stack of nanoribbons, the second semiconductor body is coupled with the second stack of nanoribbons, the second metallization structure is in contact with third and fourth semiconductor bodies between the third and fourth stacks of nanoribbons, the third and fourth semiconductor bodies including a p-type dopant, the third semiconductor body is coupled with the third stack of nanoribbons, and the fourth semiconductor body is coupled with the fourth stack of nanoribbons.

In one or more ninth embodiments, further to the first through eighth embodiments, the metallization structure is in contact with first and second semiconductor bodies between the first and second stacks of nanoribbons, the first semiconductor body is coupled with the first stack of nanoribbons, and the second semiconductor body is coupled with the second stack of nanoribbons.

In one or more tenth embodiments, further to the first through ninth embodiments, the metallization structure is a first metallization structure, the second stack of nanoribbons is between the first metallization structure and a second metallization structure, and the second metallization structure is between an isolation structure and the first and second stacks of nanoribbons.

In one or more eleventh embodiments, an apparatus includes a first stack of nanoribbons with first lattice constants over a substrate having a second lattice constant, the first stack of nanoribbons coupled with a first semiconductor body including a p-type dopant, the second lattice constant greater than the first lattice constants, a first metallization structure coupled with the first stack of nanoribbons and in contact with the first semiconductor body, the first metallization structure in a trench, a first axis of an uppermost nanoribbon of the first stack intersecting the first metallization structure, a second stack of nanoribbons with third lattice constants over the substrate, the second stack of nanoribbons coupled with a second semiconductor body including an n-type dopant, the third lattice constant greater than the second lattice constants, and a second metallization structure coupled with the second stack of nanoribbons and in contact with the second semiconductor body, the second metallization structure in the trench, a second axis of an uppermost nanoribbon of the second stack intersecting the second metallization structure.

In one or more twelfth embodiments, further to the eleventh embodiments, the first and second metallization structures include a same composition.

In one or more thirteenth embodiments, further to the eleventh or twelfth embodiments, a third metallization structure includes a metal, and the metal is over and between the nanoribbons in the first stack of nanoribbons and over and between the nanoribbons in the second stack of nanoribbons.

In one or more fourteenth embodiments, further to the eleventh through thirteenth embodiments, the first metallization structure is coupled with a third stack of nanoribbons, the trench between the first and third stacks of nanoribbons, and the second metallization structure is coupled with a fourth stack of nanoribbons, the trench between the second and fourth stacks of nanoribbons.

In one or more fifteenth embodiments, further to the eleventh through fourteenth embodiments, the apparatus is coupled to a host component, and the apparatus is coupled to a power supply through the host component.

In one or more sixteenth embodiments, a method includes growing one or more source or drain bodies between first and second nanoribbon stacks over a substrate, opening a cavity between the first and second nanoribbon stacks, depositing a film in the cavity, producing a strain in the first and second nanoribbon stacks with the film in the cavity, forming first and second gate electrodes over the first and second nanoribbon stacks, removing at least a portion of the film from the cavity, and depositing a metal on the one or more source or drain bodies.

In one or more seventeenth embodiments, further to the sixteenth embodiments, the opening the cavity between the first and second nanoribbon stacks opens the cavity between third and fourth nanoribbon stacks adjacent the first and second nanoribbon stacks, the depositing the film in the cavity deposits a first film in a first cavity between the first and second nanoribbon stacks, and also including depositing a second film in a second cavity between the third and fourth nanoribbon stacks, and the growing the one or more source or drain bodies between the first and second nanoribbon stacks grows at least a second source or drain body on the third and fourth nanoribbon stacks.

In one or more eighteenth embodiments, further to the sixteenth or seventeenth embodiments, the opening the cavity between the first and second nanoribbon stacks opens the cavity to below a lowest nanoribbon in the first nanoribbon stack and below a lowest nanoribbon in the second nanoribbon stack, and the growing the one or more source or drain bodies between the first and second nanoribbon stacks grows a first source or drain body on the first nanoribbon stack and a second source or drain body on the second nanoribbon stack.

In one or more nineteenth embodiments, further to the sixteenth through eighteenth embodiments, the growing the one or more source or drain bodies between the first and second nanoribbon stacks grows a single source or drain body coupling between the first and second nanoribbon stacks, and the opening the cavity between the first and second nanoribbon stacks etches into or through the single source or drain body to at least below a lowest nanoribbon in the first nanoribbon stack and below a lowest nanoribbon in the second nanoribbon stack.

In one or more twentieth embodiments, further to the sixteenth through nineteenth embodiments, the depositing the film in the cavity includes conformally depositing a dielectric layer in the cavity, and depositing the film on the dielectric layer.

The disclosure can be practiced with modification and alteration, and the scope of the appended claims is not limited to the embodiments so described. For example, the above embodiments may include specific combinations of features. However, the above embodiments are not limiting in this regard and, in various implementations, the above embodiments may include the undertaking only a subset of such features, undertaking a different order of such features, undertaking a different combination of such features, and/or undertaking additional features than those features explicitly listed. The scope of the patent rights should, therefore, be determined with reference to the appended claims, along with the full scope of equivalents to which such claims are entitled.

We claim:

1. An apparatus, comprising:
a first stack of nanoribbons in a first transistor structure over a substrate, the nanoribbons in the first stack comprising first lattice constants, the substrate comprising a second lattice constant, the first and second lattice constants substantially different;
a second stack of nanoribbons in a second transistor structure over the substrate, the first and second stacks of nanoribbons aligned and extending in a direction, the nanoribbons in the second stack comprising third lattice constants approximately equal to the first lattice constants; and
a metallization structure in the first and second transistor structures, the metallization structure coupled with the first and second stacks of nanoribbons, the metallization structure between an uppermost nanoribbon of the first stack of nanoribbons and an uppermost nanoribbon of the second stack of nanoribbons.

2. The apparatus of claim 1, wherein:
a semiconductor body is in contact with the metallization structure;
the semiconductor body is coupled with the first or second stacks of nanoribbons;
the semiconductor body comprises an n-type dopant; and
the first and third lattice constants are greater than the second lattice constant.

3. The apparatus of claim 1, wherein:
a semiconductor body is in contact with the metallization structure;
the semiconductor body is coupled with the first or second stacks of nanoribbons;
the semiconductor body comprises a p-type dopant; and
the second lattice constant is greater than the first and third lattice constants.

4. The apparatus of claim 1, wherein:
the metallization structure is a first metallization structure in a trench between the first and second stacks of nanoribbons;
a third stack of nanoribbons in a third transistor structure is over the substrate, the nanoribbons in the third stack comprising fourth lattice constants;
a fourth stack of nanoribbons in a fourth transistor structure is over the substrate, the third and fourth stacks of nanoribbons aligned and extending in the direction, the nanoribbons in the second stack comprising fifth lattice constants; and
a second metallization structure in the third and fourth transistor structures is in the trench, the second metallization structure coupled with the third and fourth stacks of nanoribbons, the second metallization structure between an uppermost nanoribbon of the third stack of nanoribbons and an uppermost nanoribbon of the fourth stack of nanoribbons;
the first and third lattice constants are greater than the second lattice constant; and
the second lattice constant is greater than the fourth and fifth lattice constants.

5. The apparatus of claim 4, wherein:
a first semiconductor body is in contact with the first metallization structure;
the first semiconductor body is coupled with the first or second stacks of nanoribbons;
the first semiconductor body comprises an n-type dopant;
a second semiconductor body is in contact with the second metallization structure;
the second semiconductor body is coupled with the third or fourth stacks of nanoribbons; and
the second semiconductor body comprises a p-type dopant.

6. The apparatus of claim 4, wherein the first and second metallization structures comprise a same composition.

7. The apparatus of claim 4, wherein a third metallization structure comprises a metal, and the metal is over and between the nanoribbons in the first stack of nanoribbons and over and between the nanoribbons in the third stack of nanoribbons.

8. The apparatus of claim 4, wherein:
the first metallization structure is in contact with first and second semiconductor bodies between the first and second stacks of nanoribbons, the first and second semiconductor bodies comprising an n-type dopant;
the first semiconductor body is coupled with the first stack of nanoribbons;
the second semiconductor body is coupled with the second stack of nanoribbons;
the second metallization structure is in contact with third and fourth semiconductor bodies between the third and fourth stacks of nanoribbons, the third and fourth semiconductor bodies comprising a p-type dopant;
the third semiconductor body is coupled with the third stack of nanoribbons; and
the fourth semiconductor body is coupled with the fourth stack of nanoribbons.

9. The apparatus of claim 1, wherein:
the metallization structure is in contact with first and second semiconductor bodies between the first and second stacks of nanoribbons;
the first semiconductor body is coupled with the first stack of nanoribbons; and
the second semiconductor body is coupled with the second stack of nanoribbons.

10. The apparatus of claim 1, wherein:
the metallization structure is a first metallization structure;
the second stack of nanoribbons is between the first metallization structure and a second metallization structure; and
the second metallization structure is between an isolation structure and the first and second stacks of nanoribbons.

11. An apparatus, comprising:
a first stack of nanoribbons with first lattice constants over a substrate having a second lattice constant, the first stack of nanoribbons coupled with a first semiconductor body comprising a p-type dopant, the second lattice constant greater than the first lattice constants;
a first metallization structure coupled with the first stack of nanoribbons and in contact with the first semiconductor body, the first metallization structure in a trench, a first axis of an uppermost nanoribbon of the first stack intersecting the first metallization structure;
a second stack of nanoribbons with third lattice constants over the substrate, the second stack of nanoribbons coupled with a second semiconductor body comprising an n-type dopant, the third lattice constant greater than the second lattice constants; and
a second metallization structure coupled with the second stack of nanoribbons and in contact with the second semiconductor body, the second metallization structure in the trench, a second axis of an uppermost nanoribbon of the second stack intersecting the second metallization structure.

12. The apparatus of claim 11, wherein the first and second metallization structures comprise a same composition.

13. The apparatus of claim 12, wherein a third metallization structure comprises a metal, and the metal is over and between the nanoribbons in the first stack of nanoribbons and over and between the nanoribbons in the second stack of nanoribbons.

14. The apparatus of claim 13, wherein:
the first metallization structure is coupled with a third stack of nanoribbons, the trench between the first and third stacks of nanoribbons; and
the second metallization structure is coupled with a fourth stack of nanoribbons, the trench between the second and fourth stacks of nanoribbons.

15. The apparatus of claim 14, wherein the apparatus is coupled to a host component, and the apparatus is coupled to a power supply through the host component.

16. A method, comprising:
growing one or more source or drain bodies between first and second nanoribbon stacks over a substrate;
opening a cavity between the first and second nanoribbon stacks;
depositing a film in the cavity;
producing a strain in the first and second nanoribbon stacks with the film in the cavity;
forming first and second gate electrodes over the first and second nanoribbon stacks;
removing at least a portion of the film from the cavity; and
depositing a metal on the one or more source or drain bodies.

17. The method of claim 16, wherein:
the opening the cavity between the first and second nanoribbon stacks opens the cavity between third and fourth nanoribbon stacks adjacent the first and second nanoribbon stacks;
the depositing the film in the cavity deposits a first film in a first cavity between the first and second nanoribbon stacks, and further comprising depositing a second film in a second cavity between the third and fourth nanoribbon stacks; and
the growing the one or more source or drain bodies between the first and second nanoribbon stacks grows at least a second source or drain body on the third and fourth nanoribbon stacks.

18. The method of claim 16, wherein:
the opening the cavity between the first and second nanoribbon stacks opens the cavity to below a lowest nanoribbon in the first nanoribbon stack and below a lowest nanoribbon in the second nanoribbon stack; and
the growing the one or more source or drain bodies between the first and second nanoribbon stacks grows a first source or drain body on the first nanoribbon stack and a second source or drain body on the second nanoribbon stack.

19. The method of claim 16, wherein:
the growing the one or more source or drain bodies between the first and second nanoribbon stacks grows a single source or drain body coupling between the first and second nanoribbon stacks; and
the opening the cavity between the first and second nanoribbon stacks etches into or through the single source or drain body to at least below a lowest nanoribbon in the first nanoribbon stack and below a lowest nanoribbon in the second nanoribbon stack.

20. The method of claim 16, wherein the depositing the film in the cavity comprises:
conformally depositing a dielectric layer in the cavity; and
depositing the film on the dielectric layer.
